(19) United States
(12) Patent Application Publication
(10) Pub. No.: US 2026/0362684 A1
(43) Pub. Date: Nov. 12, 2026

(54) SEMICONDUCTOR DEVICE, FORMING METHOD THEREOF, MEMORY DEVICE, AND MEMORY SYSTEM

(71) Applicant: CCSH CORPORATION, Wuhan (CN)

(72) Inventors: Kunzi LIU, Wuhan (CN); Sixian YANG, Wuhan (CN); Yi YANG, Wuhan (CN); Di WANG, Wuhan (CN); Yuancheng YANG, Wuhan (CN); Hao YU, Wuhan (CN)

(21) Appl. No.: 19/339,219

(22) Filed: Sep. 24, 2025

(30) Foreign Application Priority Data
May 7, 2025 (CN) 202510585273.5

(51) Int. Cl. H10B 12/00; H10D 80/30; H10W 90/00

(52) U.S. Cl. CPC H10B 12/50; H10B 12/09; H10B 12/312; H10B 12/482; H10B 12/488; H10D 80/30; H10W 90/00; H10W 90/792

(57) ABSTRACT

A semiconductor device includes a plurality of semiconductor bodies arranged in an array along first and second directions. A semiconductor body includes at least a first portion, a second portion, and a third portion that are arranged along a third direction. The first direction intersects the second direction, and both of the first direction and the second direction are perpendicular to the third direction. The second portion is located between the first portion and the third portion in the third direction. A material of the first portion, a material of the second portion, and a material of the third portion all include a metal semiconductor oxide. Both a chemical composition of the material of the first portion and a chemical composition of the material of the third portion are different from that of the material of the second portion.

### CROSS-REFERENCE TO RELATED APPLICATIONS

This application claims priority to Chinese Patent Application No. 202510585273.5, filed on May 07, 2025, which is hereby incorporated by reference in its entirety.

### TECHNICAL FIELD

The present disclosure relates to the field of semiconductor technology, and particularly to a semiconductor device, a forming method thereof, a memory device, and a memory system.

### BACKGROUND

With the continuous development of science and technology today, semiconductor devices are widely used in various electronic devices and electronic products. For example, a dynamic random access memory (DRAM), as a volatile memory, is a common semiconductor memory device in a computer.

### SUMMARY

In view of the above, examples of the present disclosure provide a semiconductor device, a forming method thereof, a memory device, and a memory system.

In order to achieve the above purpose, the technical solutions of the examples of the present disclosure are implemented as follows.

In a first aspect, the present disclosure provides a semiconductor device comprising a plurality of semiconductor bodies arranged in an array along a first direction and a second direction, wherein a semiconductor body of the plurality of semiconductor bodies comprises at least a first portion, a second portion, and a third portion arranged along a third direction, and the first direction intersects the second direction, and both of them are perpendicular to the third direction; wherein the second portion is located between the first portion and the third portion in the third direction; and a material of the first portion, a material of the second portion, and a material of the third portion all include a metal semiconductor oxide, and both a chemical composition of the material of the first portion and a chemical composition of the material of the third portion are different from that of the material of the second portion.

In an implementation, an elemental composition of the material of the first portion is different from that of the material of the second portion, or the elemental composition of the material of the first portion is the same as that of the material of the second portion and an elemental ratio of the material of the first portion is different from that of the material of the second portion; and an elemental composition of the material of the third portion is different from that of the material of the second portion, or the elemental composition of the material of the third portion is the same as that of the material of the second portion and an elemental ratio of the material of the third portion is different from that of the material of the second portion.

In an implementation, the material of the semiconductor body comprises at least one of indium element, gallium element, or zinc element.

In an implementation, the material of the second portion comprises at least one of aluminum element or gallium element.

In an implementation, the material of the first portion, the material of the second portion, and the material of the third portion all include indium element, and both a ratio of indium element in the material of the first portion and a ratio of indium element in the material of the third portion are higher than a ratio of indium element in the material of the second portion.

In an implementation, the semiconductor device further comprises: a plurality of word line structures extending along the second direction and arranged along the first direction, wherein one of the word line structures is located in the first direction on at least one side of the plurality of semiconductor bodies arranged along the second direction.

In an implementation, the word line structure is located in the third direction between two sides of the second portion that are opposite in the third direction.

In an implementation, the second portion is located in the third direction between two sides of the word line structure that are opposite in the third direction.

In an implementation, a ratio of a size of the second portion in the third direction to a size of the semiconductor body in the third direction ranges from 55% to 80%.

In an implementation, the semiconductor device further comprises: connection structures located on one of two opposite sides of the semiconductor body along the third direction, wherein one of the connection structures is connected to the first portion of one of the semiconductor bodies; and bit line structures located on the other side of two opposite sides of the semiconductor body along the third direction, wherein one of the bit line structures is connected to the third portions of the plurality of semiconductor bodies arranged along the first direction.

In an implementation, the semiconductor body further comprises a fourth portion and a fifth portion, wherein the fourth portion and the fifth portion are respectively located on two opposite sides of the second portion along the third direction; the fourth portion surrounds the first portion and is connected to the connection structure; and the fifth portion surrounds the third portion and is connected to the bit line structure.

In an implementation, both the fourth portion and the fifth portion are connected to the second portion, and both a chemical composition of a material of the fourth portion and a chemical composition of a material of the fifth portion are the same as that of the material of the second portion.

In an implementation, the semiconductor device further comprises: a first isolation structure located on one of two opposite sides of the semiconductor body along the first direction and comprising a first conductive layer extending along the second direction; and a dielectric layer located between the first conductive layer and the semiconductor body in the first direction.

In an implementation, the first conductive layer is located in the third direction between two sides of the second portion that are opposite in the third direction.

In an implementation, the semiconductor device further comprises: an insulating layer located on one of two opposite sides of the plurality of semiconductor bodies along the third direction, wherein the connection structure penetrates through the insulation layer along the third direction and comprises a second conductive layer and a conductive structure, and the second conductive layer is located between the conductive structure and the insulating layer and between the conductive structure and the semiconductor body.

In an implementation, the semiconductor device further comprises: a second isolation structure located between two adjacent word line structures in the first direction, wherein the two adjacent word line structures in the first direction are symmetrically distributed on both sides of the second isolation structure along the first direction.

In an implementation, the semiconductor device comprises a memory array and a peripheral circuit coupled to the memory array, wherein the memory array comprises the plurality of semiconductor bodies and a plurality of capacitor structures arranged in an array along the first and second directions, the plurality of capacitor structures and the plurality of semiconductor bodies are stacked along the third direction, and one of the capacitor structures is coupled to the first portion of one of the semiconductor bodies.

In a second aspect, the present disclosure provides a memory device comprising a memory array and a peripheral circuit coupled to the memory array, wherein the memory array comprises a plurality of memory cells arranged in an array along a first direction and a second direction, a memory cell of the plurality of memory cells comprises a semiconductor body and a capacitor structure stacked along a third direction, and the first direction intersects the second direction, and both of them are perpendicular to the third direction, wherein the semiconductor body comprises at least a first portion, a second portion, and a third portion arranged along the third direction, and wherein the second portion is located between the first portion and the third portion in the third direction, the first portion is coupled to the capacitor structure, a material of the first portion, a material of the second portion, and a material of the third portion all include a metal semiconductor oxide, and both a chemical composition of the material of the first portion and a chemical composition of the material of the third portion are different from that of the material of the second portion.

In an implementation, an elemental composition of the material of the first portion is different from that of the material of the second portion, or the elemental composition of the material of the first portion is the same as that of the material of the second portion and the elemental ratio of the material of the first portion is different from that of the material of the second portion; and an elemental composition of the material of the third portion is different from that of the material of the second portion, or the elemental composition of the material of the third portion is the same as that of the material of the second portion and the elemental ratio of the material of the third portion is different from that of the material of the second portion.

In an implementation, the material of the semiconductor body comprises at least one of indium element, gallium element, or zinc element.

In an implementation, the material of the second portion comprises at least one of aluminum element or gallium element.

In an implementation, the material of the first portion, the material of the second portion, and the material of the third portion all include indium element, and both a ratio of indium element in the material of the first portion and a ratio of indium element in the material of the third portion are higher than a ratio of indium element in the material of the second portion.

In an implementation, the semiconductor device further comprises: a plurality of word line structures extending along the second direction and arranged along the first direction, wherein one of the word line structures is located in the first direction on at least one side of the plurality of semiconductor bodies arranged along the second direction.

In an implementation, the second portion is located in the third direction between two sides of the word line structure that are opposite in the third direction.

In an implementation, a ratio of a size of the second portion in the third direction to a size of the semiconductor body in the third direction ranges from 55% to 80%.

In an implementation, the memory device further comprises: connection structures located on one of two opposite sides of the semiconductor body along the third direction, and one of two opposite ends of one of the connection structures in the third direction is connected to the first portion of one semiconductor body, and the other end of two opposite ends of the one of the connection structures in the third direction is connected to the capacitor structure; and bit line structures located on the other side of two opposite sides of the semiconductor body along the third direction, wherein one of the bit line structures is connected to the third portions of the plurality of semiconductor bodies arranged along the first direction.

In an implementation, the semiconductor body further comprises a fourth portion and a fifth portion, wherein the fourth portion and the fifth portion are respectively located on two opposite sides of the second portion along the third direction; the fourth portion surrounds the first portion and is connected to the connection structure; and the fifth portion surrounds the third portion and is connected to the bit line structure.

In an implementation, both the fourth portion and the fifth portion are connected to the second portion, and both a chemical composition of a material of the fourth portion and a chemical composition of a material of the fifth portion are the same as that of the material of the second portion.

In an implementation, the memory device further comprises: a first isolation structure located on one of two opposite sides of the semiconductor body along the first direction and comprising a first conductive layer extending along the second direction; and a dielectric layer located between the first conductive layer and the semiconductor body in the first direction.

In an implementation, the first conductive layer is located in the third direction between two sides of the second portion that are opposite in the third direction.

In an implementation, the memory device comprises a first semiconductor structure and a second semiconductor structure stacked along the third direction, and a bonding layer located between the first semiconductor structure and the second semiconductor structure, wherein the memory array is located in the first semiconductor structure, the peripheral circuit is located in the second semiconductor structure, and the memory array and the peripheral circuit are coupled through a bonding structure in the bonding layer.

In a third aspect, the present disclosure provides a memory system comprising: at least one semiconductor device comprising a plurality of semiconductor bodies arranged in an array along a first direction and a second direction, wherein a semiconductor body of the plurality of semiconductor bodies comprises at least a first portion, a second portion, and a third portion arranged along a third direction, the first direction intersects the second direction, and both of them are perpendicular to the third direction, and wherein the second portion is located between the first portion and the third portion in the third direction, a material of the first portion, a material of the second portion, and a material of the third portion all include a metal semiconductor oxide, and both a chemical composition of the material of the first portion and a chemical composition of the material of the third portion are different from that of the material of the second portion; and a controller coupled to the at least one semiconductor device and configured to control the semiconductor device.

In a fourth aspect, the present disclosure provides a forming method of a semiconductor device, comprising: forming a plurality of semiconductor bodies arranged in an array along a first direction and a second direction, wherein a semiconductor body of the plurality of semiconductor bodies comprises at least a first portion, a second portion, and a third portion arranged along a third direction, the first direction intersects the second direction, and both of them are perpendicular to the third direction, wherein the second portion is located between the first portion and the third portion in the third direction, a material of the first portion, a material of the second portion, and a material of the third portion all include a metal semiconductor oxide, and both a chemical composition of the material of the first portion and a chemical composition of the material of the third portion are different from that of the material of the second portion.

In an implementation, the forming method comprises: providing a substrate comprising a plurality of sacrificial pillars arranged in an array along the first direction and the second direction, the sacrificial pillars extending along the third direction, wherein the substrate further comprises word line structures extending along the second direction and arranged along the first direction, and one of the word line structures is located in the first direction on at least one side of the plurality of sacrificial pillars arranged along the second direction; and forming the semiconductor body in the substrate, wherein the position occupied by the semiconductor body in the substrate is the same as the position occupied by the sacrificial pillar in the substrate.

In an implementation, the forming method further comprises: forming an insulation layer on one of two opposite sides of the substrate along the third direction, and forming a plurality of connection structures that penetrate through the insulation layer along the third direction.

In an implementation, the forming the semiconductor body comprises: removing the sacrificial pillar from one side, away from the connection structure, of two opposite sides of the substrate along the third direction, to form a first trench, wherein a bottom of the first trench exposes the connection structure; forming a first material layer in the first trench, and etching the first material layer to form the first portion and a second trench; forming a second material layer in the second trench, and etching the second material layer to form the second portion and a third trench; and forming the third portion in the third trench.

In an implementation, the forming the semiconductor body comprises: before forming the insulation layer and the connection structure, removing a portion of the sacrificial pillar from one of two opposite sides of the substrate along the third direction to form a fourth trench; forming a sacrificial layer in the fourth trench, wherein the sacrificial layer is located at least at a bottom of the fourth trench and is connected to a remaining portion of the sacrificial pillar; forming the first portion in the remaining space of the fourth trench; after forming the insulation layer and the connection structure, removing the remaining portion of the sacrificial pillar and the sacrificial layer from one side, away from the connection structure, of two opposite sides of the substrate along the third direction, to form a fifth trench; and forming the second and third portions in the fifth trench.

In an implementation, the sacrificial layer is located at the bottom and sidewall of the fourth trench, and the forming the second and third portions in the fifth trench comprises: forming, in the fifth trench, a fourth portion surrounding the first portion and connected to the connection structure, the second portion connected to the fourth portion, and a sixth portion connected to the second portion; etching the sixth portion to form a fifth portion connected to the second portion and a sixth trench surrounded by the fifth portion; and forming the third portion in the sixth trench.

In an implementation, the substrate further comprises a first isolation structure and a dielectric layer, wherein the first isolation structure is located on one of two opposite sides of the sacrificial pillar along the first direction and comprises a first conductive layer extending along the second direction, and the dielectric layer is located between the first conductive layer and the sacrificial pillar in the first direction.

In an implementation, the substrate further comprises a second isolation structure located between two adjacent word line structures in the first direction, wherein the two adjacent word line structures in the first direction are symmetrically distributed on both sides of the second isolation structure along the first direction.

In an implementation, the method further comprises: forming bit line structures on one side, away from the connection structure, of two opposite sides of the semiconductor body along the third direction, wherein one of the bit line structures is connected to the third portions of the plurality of semiconductor bodies arranged along the first direction.

### BRIEF DESCRIPTION OF THE DRAWINGS

FIG. 1 is a schematic diagram of an electronic device provided by an example of the present disclosure;

FIG. 2 is a schematic diagram of a memory device provided by an example of the present disclosure;

FIG. 3 is a structural diagram I of a semiconductor device provided by an example of the present disclosure;

FIG. 4 is a cross-sectional view taken along the AA' line in FIG. 3;

FIG. 5 is a structural diagram II of a semiconductor device provided by an example of the present disclosure;

FIG. 6 is a structural diagram III of a semiconductor device provided by an example of the present disclosure;

FIG. 7 is a structural diagram IV of a semiconductor device provided by an example of the present disclosure;

FIG. 8 is a structural diagram of a memory device including a semiconductor device provided by an example of the present disclosure;

FIG. 9 is a schematic flow chart of a forming method of a semiconductor device provided by an example of the present disclosure;

FIGS. 10-12 are structural diagrams of a forming process of a semiconductor device provided by an example of the present disclosure;

FIG. 13 is a schematic flow chart I of forming a semiconductor body in a substrate provided by an example of the present disclosure;

FIGS. 14-19 are structural diagrams of a forming process of a semiconductor device provided by an example of the present disclosure;

FIG. 20 is a schematic flow chart II of forming a semiconductor body in a substrate provided by an example of the present disclosure;

FIGS. 21-30 are structural diagrams of a forming process of a semiconductor device provided by an example of the present disclosure;

FIG. 31 is a schematic flow chart of forming a second portion and a third portion in a fifth trench provided by an example of the present disclosure; and

FIGS. 32-35 are structural diagrams of a forming process of a semiconductor device provided by an example of the present disclosure.

### DETAILED DESCRIPTION

Implementations of the present disclosure will be described in more detail below with reference to the accompanying drawings. Although the implementations of the present disclosure are shown in the drawings, it should be understood that the present disclosure may be implemented in various forms and should not be limited by the implementations set forth herein. Rather, these implementations are provided so that the present disclosure can be more thoroughly understood, and the scope of the disclosure can be completely conveyed to those skilled in the art.

In the following description, numerous details are given in order to provide a more thorough understanding of the present disclosure. However, it will be apparent to those skilled in the art that the present disclosure may be practiced without one or more of these details. In other examples, to avoid confusion with the present disclosure, some technical features known in the art are not described; that is, not all of the features of actual examples are described herein, and well-known functions and structures are not described in detail.

In the drawings, same reference number refers to same element throughout.

It should be understood that spatial relationship terms such as “under”, “below”, “lower”, “beneath”, “above”, “upper”, and the like may be used herein for ease of description to describe one element or feature's relationship to another element or feature shown in the figures. It should be appreciated that the spatial relationship terms are intended to include different orientations of the device in use and operation in addition to the orientation shown in the figures. For example, if a device in the figures is flipped, then an element or feature described as being “below” or “beneath” or “under” another element or feature will be oriented “on” the another element or feature. Thus, the example terms “below” and “under” can include both upper orientation and lower orientation. The device may additionally be oriented (rotated 90 degrees or another orientation) and the spatial description terms used herein are interpreted accordingly.

The term used herein is for the purpose of describing examples only and not as a limitation of the present disclosure. As used herein, the singular forms “a,” “an,” and “the” are also intended to include the plural forms unless the context clearly indicates otherwise. It should also be understood that the terms “consisting of” and / or “including”, when used in this specification, determine the presence of stated features, integers, steps, operations, elements and / or components, but do not preclude the presence or addition of one or more other features, integers, steps, operations, elements, components and / or groups. As used herein, the term “and / or” includes any and all combinations of related listed items.

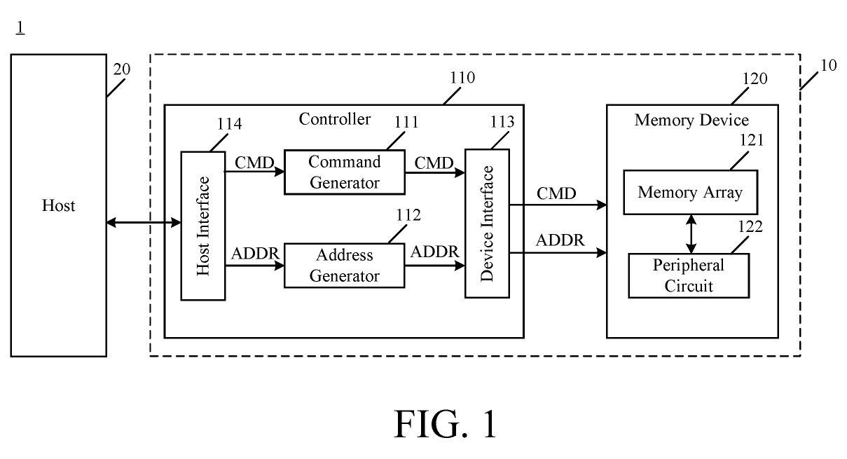

FIG. 1 is a schematic diagram of an electronic device provided by an example of the present disclosure. The electronic device 1 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having storage therein.

As shown in FIG. 1, the electronic device 1 may include a memory system 10 and a host 20, and the memory system 10 may include a controller 110 and a memory device 120. The host 20 may include a processor of the electronic device 1, such as a central processing unit (CPU), or a system on chip (SoC), such as an application processor (AP). The controller 110 is coupled to both the host 20 and the memory device 120, and may be configured to communicate with the host 20 and control the memory device 120.

In some examples, the controller 110 may be configured to control operations of the memory device 120, such as read operation, erase operation, write operation, refresh operation, etc. In some implementations, the controller 110 is also configured to process error correction codes (ECCs) on data read from or written to the memory device 120. In other implementations, the controller 110 may also be configured to perform any other suitable operations, such as formatting the memory device 120.

In some examples, the controller 110 may receive data, commands, and addresses from the host 20 and may send data, commands, and addresses to the memory device 120. In an example, the controller 110 may include a command generator 111, an address generator 112, a device interface 113, and a host interface 114. The controller 110 may receive data, commands, and addresses from the host 20 through the host interface 114, decode commands received from the host 20 through the command generator 111 to generate an access command CMD, and provide the access command CMD to the memory device 120 through the device interface 113. The controller 110 may decode an address received from the host interface 114 through the address generator 112 to generate an address ADDR to be accessed in the memory array 121, and may provide the address ADDR to be accessed to the memory device 120 through the device interface 113. The access command may be a signal instructing the memory device 120 to write or read data by accessing one or more memory cells in the memory array 121 corresponding to the address ADDR. In addition, the controller 110 may also send a refresh command to the memory device 120, which may be a signal instructing the memory device 120 to read and rewrite data by accessing one or more memory cells in the memory array 121 corresponding to the address ADDR.

In some examples, the memory device 120 may be a random access memory (RAM), such as a dynamic random access memory (DRAM), a synchronous dynamic random access memory (SDRAM), a static random access memory (SRAM), a double rate SDRAM (DDR SDRAM), a phase-change random access memory (PRAM), a resistive random access memory (ReRAM), a magnetic random access memory (MRAM), etc. Hereinafter, take the memory device 120 being a DRAM as an example for illustration.

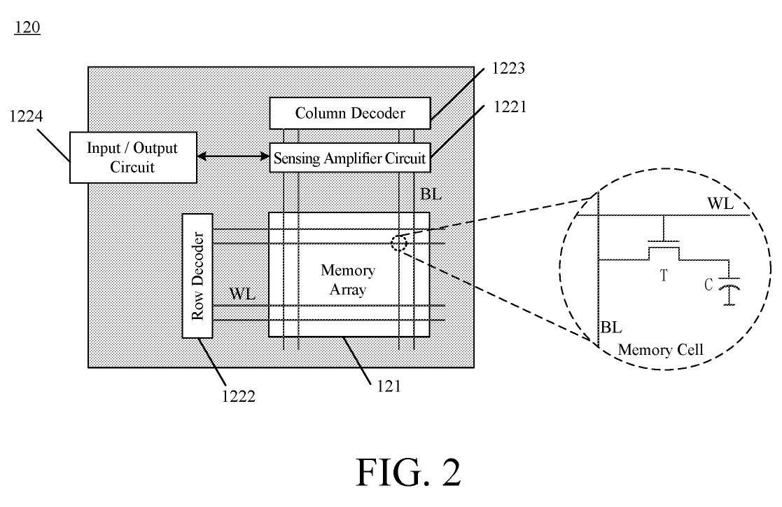

In some examples, FIG. 2 is a schematic diagram of a memory device provided by an example of the present disclosure. Referring to FIGS. 1 and 2, the memory device includes a memory array 121 and a peripheral circuit 122 coupled to the memory array 121. The peripheral circuit 122 may include a sensing amplifier circuit 1221, a row decoder 1222, a column decoder 1223, an input/output buffer 1224, etc. The memory array 121 includes a plurality of memory cells arranged in an array, the plurality of memory cells located in the same row are coupled to a word line WL, and the plurality of memory cells located in the same column are coupled to a bit line BL. Each memory cell includes a transistor T and a capacitor C. The word line WL is connected to a gate of the transistor T, the bit line BL is connected to one of a source and a drain of the transistor T, the other of the source and the drain of the transistor T is connected to one electrode of the capacitor C, and the other electrode of the capacitor C is connected to a fixed voltage. The memory cell is configured to store l or 0 using the amount of charge stored by the capacitor C. By specifying row and column addresses, various memory cells in DRAM chip may be independently accessed, and read, write, or refresh operations are performed on the data stored therein.

In order to meet the demands of modern computing systems for large capacity, high performance, and miniaturization of memory devices, how to improve the electrical performance and reliability of DRAM while improving its integration has become an urgent problem to be solved. In this regard, the following implementations are proposed in the present disclosure.

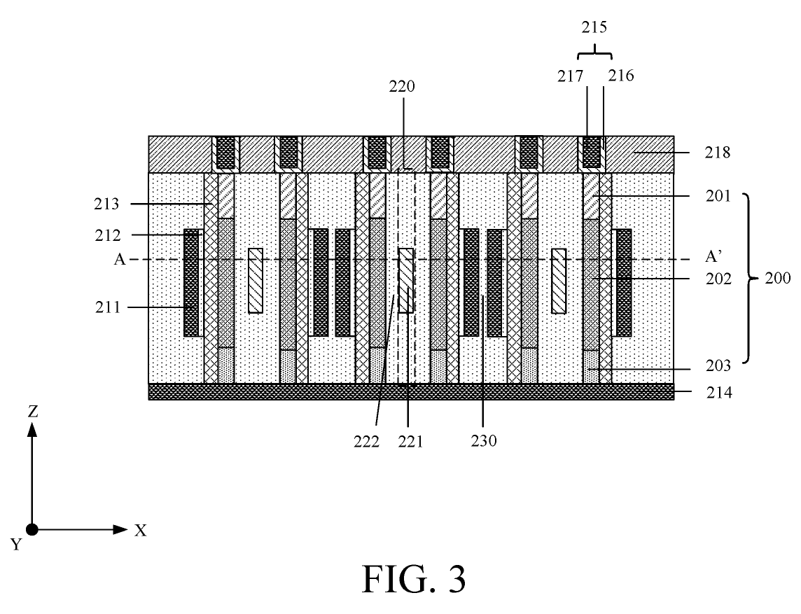

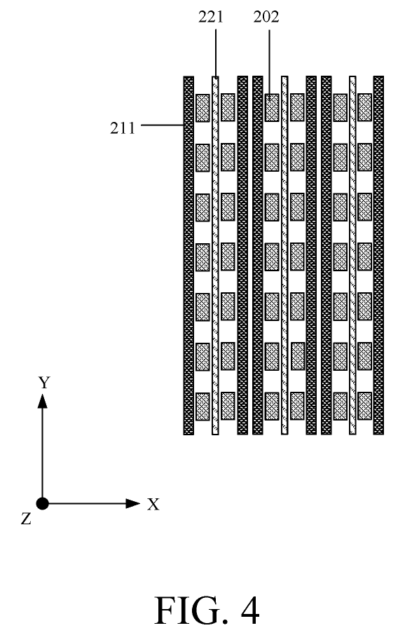

The present disclosure provides a semiconductor device. FIG. 3 is a structural diagram of a semiconductor device provided by an example of the present disclosure, and FIG. 4 is a cross-sectional view taken along the AA' line in FIG. 3. Referring to FIGS. 3 and 4, the semiconductor device includes a plurality of semiconductor bodies 200 arranged in an array along a first direction and a second direction. The semiconductor body 200 includes at least a first portion 201, a second portion 202, and a third portion 203 arranged along a third direction, wherein the second portion 202 is located between the first portion 201 and the third portion 203 in the third direction, a material of the first portion 201, a material of the second portion 202, and a material of the third portion 203 all include a metal semiconductor oxide, and both the chemical composition of the material of the first portion 201 and the chemical composition of the material of the third portion 203 is different from that of the material of the second portion 202.

In an example of the present disclosure, the first direction intersects the second direction, and both of them are perpendicular to the third direction. Here, taking the first direction being the X direction, the second direction being the Y direction, and the third direction being the Z direction as examples.

In some examples, different chemical compositions may include two situations: different elemental compositions, and the same elemental composition but different elemental ratios. In an example, in the semiconductor device provided by the example of the present disclosure, the elemental composition of the material of the first portion 201 is different from that of the material of the second portion 202, or the elemental composition of the material of the first portion 201 is the same as that of the material of the second portion 202 and the elemental ratio of the material of the first portion 201 is different from that of the material of the second portion 202. The elemental composition of the material of the third portion 203 is different from that of the material of the second portion 202, or the elemental composition of the material of the third portion 203 is the same as that of the material of the second portion 202 and the elemental ratio of the material of the third portion 203 is different from that of the material of the second portion 202.

In some examples, referring to FIGS. 3 and 4, the semiconductor device further comprises a plurality of word line structures 211 extending along the second direction and arranged along the first direction, wherein one of the word line structures 211 is located in the first direction on at least one side of a plurality of semiconductor bodies 200 arranged along the second direction.

Here, the word line structure 211 may serve as a gate of a transistor, a dielectric layer between the word line structure 211 and the semiconductor body 200, such as a composite dielectric layer composed of the dielectric layers 212 and 213, may serve as a gate dielectric layer of the transistor, and the semiconductor body 200 may serve as an active region of the transistor, thereby forming a plurality of transistors arranged in an array along the first and second directions.

In some examples, referring to FIG. 3, the semiconductor device further comprises: connection structures 215 located on one of two opposite sides of the semiconductor body 200 along the third direction, wherein one of the connection structures 215 is connected to a first portion 201 of one of the semiconductor bodies 200; and bit line structures 214 located on the other side of two opposite sides of the semiconductor body 200 along the third direction, wherein one of the bit line structures 214 is connected to third portions 203 of the plurality of semiconductor bodies 200 arranged along the first direction.

In some examples, both the connection structure 215 and the bit line structure 214 include a conductive material. Here, the conductive material may be one or more of a doped semiconductor material (such as doped silicon, doped germanium, etc.), a conductive metal nitride (such as titanium nitride, tantalum nitride, etc.), a metal material (such as aluminum, copper, tungsten, titanium, tantalum, etc.), and a metal semiconductor compound (such as tungsten silicide, cobalt silicide, titanium silicide, etc.).

In an example of the present disclosure, the first portion 201, the second portion 202, and the third portion 203 all include a metal semiconductor oxide, that is, the transistor including the semiconductor body 200 uses a metal semiconductor oxide as a channel material. Compared with the channel material such as polycrystalline silicon, the metal semiconductor oxide has advantages such as higher electron mobility, lower leakage current, and easier control of threshold voltage, which are conducive to improving the electrical performance of the semiconductor device. Furthermore, both the chemical composition of the material of the first portion 201 and the chemical composition of the material of the third portion 203 are different from that of the material of the second portion 202. Compared to a semiconductor body with a single component, the length of the channel extension region of the transistor including the semiconductor body 200 may be smaller, which enables the transistor to have better performance, such as a higher on-state current (Iₒₙ) and a lower off-state current (I_{off}), thereby improving the driving capability of the transistor and reducing its leakage current, which is conducive to further improving the electrical performance and reliability of the semiconductor device. Below, this will be described with reference to examples.

In some examples, the material of the semiconductor body 200 includes at least one of indium element (In), gallium element (Ga), or zinc element (Zn).

In some examples, the material of the first portion 201 and the material of the third portion 203 may include tin element (Sn).

In some examples, both the material of the first portion 201 and the material of the third portion 203 may include at least one of indium zinc oxide (IZO), indium tin zinc oxide (ITZO), or indium tin oxide (ITO). The material of the first portion 201 and the material of the third portion 203 may not include gallium element, but include at least one of zinc element or tin element, with high oxygen hole concentration and electron mobility, which may reduce the resistance of the semiconductor body 200, the contact resistance between the semiconductor body 200 and the connection structure 215, and the contact resistance between the semiconductor body 200 and the bit line structure 214, to improve the on-state current of the transistor including the semiconductor body 200, thereby improving the driving capability of the transistor.

In some examples, the material of the second portion 202 includes at least one of aluminum element (Al) or gallium element.

In some examples, the material of the second portion 202 includes indium gallium zinc oxide (IGZO), and includes gallium element, which may suppress the formation of oxygen vacancies and have higher stability, resulting in lower off-state current of the transistor including the semiconductor body 200, thereby reducing the leakage current of the transistor.

In some examples, the material of the second portion 202 includes indium aluminum zinc oxide (IAZO) or indium aluminum gallium zinc oxide (IAGZO), that is, aluminum element may replace gallium element or a part of gallium element in the indium gallium zinc oxide to further increase the ionization energy of the material, so that the material of the second portion 202 has a higher stability. Therefore, the threshold voltage of the transistor including the semiconductor body 200 may be further increased and the off-state current of the transistor may be reduced, thereby reducing the leakage current of the transistor.

In some examples, the elemental composition of the material of the first portion 201 is different from that of the material of the second portion 202, and the elemental composition of the material of the third portion 203 is different from that of the material of the second portion 202. For example, the material of the second portion 202 includes at least one of indium gallium zinc oxide, indium aluminum zinc oxide, or indium aluminum gallium zinc oxide, and both the material of the first portion 201 and the material of the third portion 203 include at least one of indium zinc oxide, indium tin zinc oxide, or indium tin oxide. Therefore, the transistor including the semiconductor body 200 may have both a high on-state current and a low off-state current, and therefore have both strong driving capability and high reliability.

In some examples, the material of the first portion 201, the material of the second portion 202, and the material of the third portion 203 all include an indium element, and both the ratio of indium element in the material of the first portion 201 and the ratio of indium element in the material of the third portion 203 are higher than the ratio of indium element in the material of the second portion 202.

In some examples, the elemental composition of the material of the first portion 201 is the same as that of the material of the second portion 202, but the elemental ratio of the material of the first portion 201 is different from that of the material of the second portion 202, and the elemental composition of the material of the third portion 203 is the same as that of the material of the second portion 202, but the elemental ratio of the material of the third portion 203 is different from that of the material of the second portion 202. For example, the material of the first portion 201, the material of the second portion 202, and the material of the third portion 203 may all include indium gallium zinc oxide, and both the ratio of indium element in the material of the first portion 201 and the ratio of indium element in the material of the third portion 203 are higher than the ratio of indium element in the material of the second portion 202, and thus both the material of the first portion 201 and the material of the third portion 203 may have a higher electron mobility compared to the material of the second portion 202, which is beneficial for increasing the on-state current of the transistor including the semiconductor body 200.

In some examples, the elemental composition of the material of the first portion 201 is different from that of the material of the second portion 202, and the elemental composition of the material of the third portion 203 is the same as that of the material of the second portion 202, but the elemental ratio of the material of the third portion 203 is different from that of the material of the second portion 202. For example, the material of the first portion 201 may include at least one of indium zinc oxide, indium tin zinc oxide, or indium tin oxide, and the material of the second portion 202 and the material of the third portion 203 may both include indium gallium zinc oxide, and the ratio of indium element in the material of the third portion 203 is higher than the ratio of indium element in the material of the second portion 202, and thus both the material of the first portion 201 and the material of the third portion 203 may have a higher electron mobility compared to the material of the second portion 202, which is beneficial for increasing the on-state current of the transistor including semiconductor body 200.

In some examples, the elemental composition of the material of the first portion 201 is the same as that of the material of the second portion 202, but the elemental ratio of the material of the first portion 201 is different from that of the material of the second portion 202, and the elemental composition of the material of the third portion 203 is different from that of the material of the second portion 202. For example, the material of the third portion 203 may include at least one of indium zinc oxide, indium tin zinc oxide, or indium tin oxide, and both the material of the second portion 202 and the material of the first portion 201 may include indium gallium zinc oxide, and the ratio of indium element in the material of the first portion 201 is higher than the ratio of indium element in the material of the second portion 202, and thus both the material of the first portion 201 and the material of the third portion 203 may have a higher electron mobility compared to the material of the second portion 202, which is beneficial for increasing the on-state current of the transistor including the semiconductor body 200.

In an example of the present disclosure, the material of the first portion 201 and the material of the third portion 203 may have a higher electron mobility compared to the material of the second portion 202, which may reduce the resistance of the semiconductor body 200, the contact resistance between the first portion 201 and the connection structure 215, and the contact resistance between the third portion 203 and the bit line structure 214, thereby increasing the on-state current of the transistor including the semiconductor body 200. The material of the second portion 202 may have a higher ionization energy and stability compared to the material of the first portion 201 and the material of the third portion 203, thereby enabling the transistor to have a higher threshold voltage and a lower off-state current. Thus, the transistor including the semiconductor body 200 may have both strong driving capability and high reliability.

In the semiconductor device provided in the present disclosure, in addition to the material compositions of the first portion 201, the second portion 202, and the third portion 203 affecting the performance of the semiconductor device, the relative sizes of the first portion 201, the second portion 202, and the third portion 203, and the relative position relationship between the second portion 202 and the word line structure 211, also affect the performance of the semiconductor device.

In some examples, referring to FIG. 3, the word line structure 211 is located in the third direction between two sides of the second portion 202 that are opposite in the third direction.

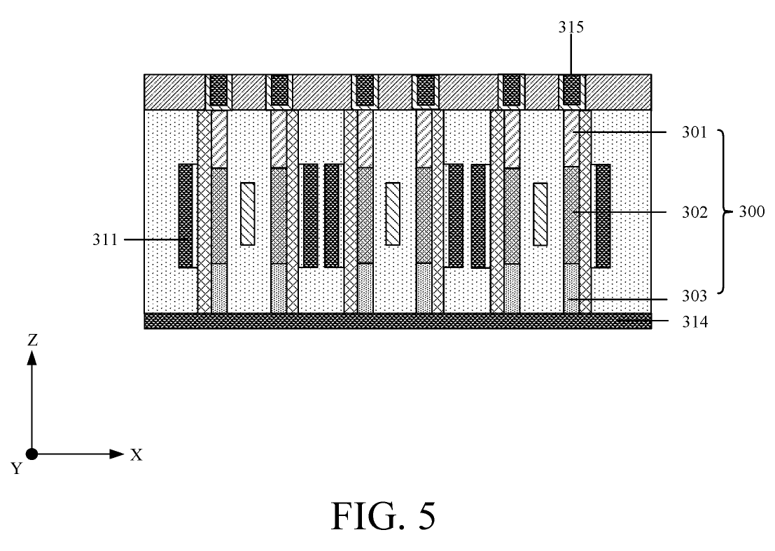

In other examples, FIG. 5 is a schematic diagram of a semiconductor device provided by examples of the present disclosure, wherein the second portion 302 is located in the third direction between two sides of the word line structure 311 that are opposite in the third direction. Here, the structure of the semiconductor device shown in FIG. 5 is similar to that of the semiconductor device shown in FIG. 3, including a semiconductor body 300, a word line structure 311, a bit line structure 314, and a connection structure 315. The semiconductor body 300 includes a first portion 301, a second portion 302, and a third portion 303.

In some examples, a ratio of the size of the second portion in the third direction to the size of the semiconductor body in the third direction ranges from 55% to 80%.

It should be noted that, on one hand, in order to make the transistor including the semiconductor body have a high threshold voltage and a low off-state current, the ratio of the size of the second portion in the third direction to the size of the semiconductor body in the third direction cannot be too low, because both the material of the first portion and the material of the third portion have a high electron mobility. If the ratio is too high, it may cause the electron drift speed to be too fast, resulting in a decrease in the threshold voltage of the transistor and an increase in the off-state current. On the other hand, in order to make the transistor including the semiconductor body have a high on-state current, the ratio of the size of the second portion in the third direction to the size of the semiconductor body in the third direction cannot be too high, because the material of the second portion has a low electron mobility. If the ratio is too high, it may cause the resistance of the semiconductor body to be too high, which may reduce the driving capability of the transistor.

In an example, referring to FIG. 3, the word line structure 211 is located in the third direction between two sides of the second portion 202 that are opposite in the third direction, and the ratio of the size of the second portion 202 in the third direction to the size of the semiconductor body 200 in the third direction ranges from 65% to 80%, the ratio of the size of the first portion 201 in the third direction to the size of the semiconductor body 200 in the third direction ranges from 10% to 25%, and the ratio of the size of the third portion 203 in the third direction to the size of the semiconductor body 200 in the third direction ranges from 25% to 10%.

In an example, referring to FIG. 5, the second portion 302 is located in the third direction between two sides of the word line structure 311 that are opposite in the third direction, and the ratio of the size of the second portion 302 in the third direction to the size of the semiconductor body 300 in the third direction ranges from 55% to 65%, the ratio of the size of the first portion 301 in the third direction to the size of the semiconductor body 300 in the third direction ranges from 10% to 35%, and the ratio of the size of the third portion 303 in the third direction to the size of the semiconductor body 300 in the third direction ranges from 35% to 10%.

Based on the settings of the materials of the first, second, and third portions provided in the above examples, when the second portion 302 is located in the third direction between two sides of the word line structure 311 that are opposite in the third direction, the word line structure 311 may achieve over coverage of the second portion 302, thereby improving the control capability of the word line structure 311 over the semiconductor body 300 while increasing the on-state current of the transistor including the semiconductor body 300 and reducing its off-state current. In addition, in the case where the size of the word line structure 311 in the third direction remains unchanged and the word line structure 311 achieves over coverage of the second portion 302, the size of the first portion 301 and the third portion 303 in the third direction may be relatively large, which is conducive to further compressing the length of the channel extension region in the semiconductor body 300 to reduce the resistance of the semiconductor body 300, thereby achieving a higher on-state current.

It should be noted that other structures in the semiconductor device shown in FIG. 5 are the same as the structures in the semiconductor device shown in FIG. 3. Next, the semiconductor device shown in FIG. 3 will be taken as an example to describe other structures in the semiconductor device provided by the present disclosure.

In some examples, referring to FIGS. 3 and 4, the semiconductor device further comprises: a first isolation structure 220 located on one of two opposite sides of the semiconductor body 200 along the first direction, wherein the first isolation structure 220 includes a first conductive layer 221 extending along the second direction; and a dielectric layer 222 located between the first conductive layer 221 and the semiconductor body 200 in the first direction.

In some examples, referring to FIG. 3, the first conductive layer 221 is located in the third direction between two sides of the second portion 202 that are opposite in the third direction.

In some examples, the first conductive layer 221 includes a conductive material. Here, the conductive material may be one or more of a doped semiconductor material (such as doped silicon, doped germanium, etc.), a conductive metal nitride (such as titanium nitride, tantalum nitride, etc.), a metal material (such as aluminum, copper, tungsten, titanium, tantalum, etc.), and a metal semiconductor compound (such as tungsten silicide, cobalt silicide, titanium silicide, etc.).

In an example of the present disclosure, the first conductive layer 221 in the first isolation structure 220 may serve as a back gate, and one first conductive layer 221 may be shared by a plurality of semiconductor bodies 200 located on two opposite sides thereof in the first direction. The first conductive layer 221 includes a conductive material and may be applied with a voltage to adjust the threshold voltage of the transistor including the semiconductor body 200, reduce leakage current, and may reduce parasitic capacitance between adjacent semiconductor bodies 200 in the first direction, which is conducive to further improving the reliability of the semiconductor device.

In some examples, referring to FIG. 3, the semiconductor device further comprises an insulating layer 218 located on one of two opposite sides of a plurality of semiconductor bodies 200 along the third direction. The connection structure 215 penetrates through the insulating layer 218 along the third direction, and includes a second conductive layer 216 and a conductive structure 217. The second conductive layer 216 is located between the conductive structure 217 and the insulating layer 218 and between the conductive structure 217 and the semiconductor body 200.

In some examples, the insulating layer 218 may include a dielectric material, such as silicon nitride. The conductive structure 217 may include a conductive material, such as tungsten. The second conductive layer 216 may include a conductive material, such as titanium nitride. The second conductive layer 216 is connected to the first portion 201, which may reduce the contact resistance between the conductive structure 217 and the first portion 201.

In some examples, referring to FIG. 3, the semiconductor device further comprises a second isolation structure 230 located between two adjacent word line structures 211 in the first direction. The two adjacent word line structures 211 in the first direction are symmetrically distributed on both sides of the second isolation structure 230 along the first direction.

In some examples, the second isolation structure 230 may include a dielectric material, such as silicon oxide.

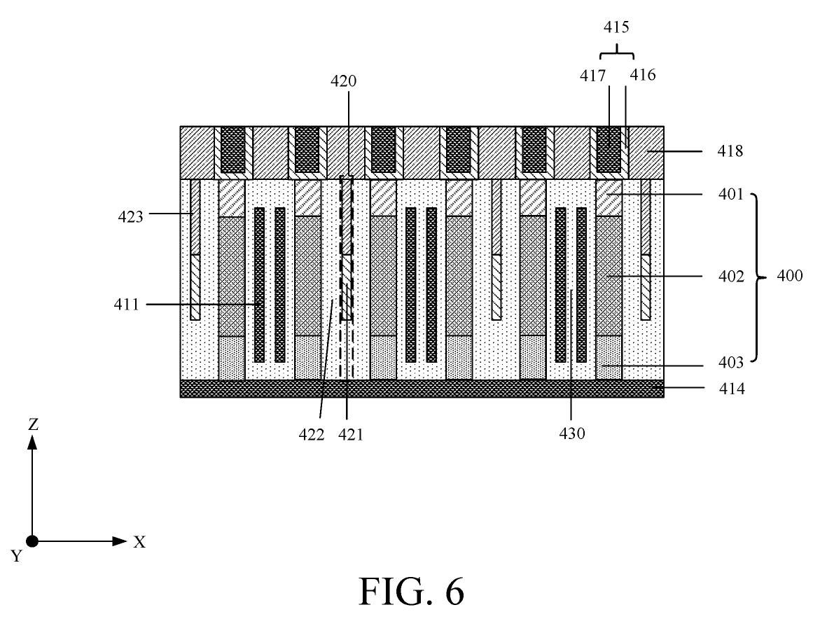

In some examples, FIG. 6 is a structural diagram of a semiconductor device provided by an example of the present disclosure. Referring to FIG. 6, the semiconductor device includes a semiconductor body 400, a word line structure 411, an insulation layer 418, a connection structure 415 (including a second conductive layer 416 and a conductive structure 417), a bit line structure 414, a first isolation structure 420, a dielectric layer 422, and a second isolation structure 430. The semiconductor body 400 includes a first portion 401, a second portion 402, and a third portion 403 arranged along a third direction. A material of the first portion 401, a material of the second portion 402, and a material of the third portion 403 all include a metal semiconductor oxide, and both the chemical composition of the material of the first portion 401 and the chemical composition of the material of the third portion 403 are different from that of the material of the second portion 402.

Here, the first isolation structure 420 may include a first conductive layer 421 and a sub isolation structure 423 between the insulating layer 418 and the first conductive layer 421 in the third direction. The size of the sub isolation structure 423 in the first direction may be substantially the same as that of the first conductive layer 421 in the first direction, and the first sub isolation structure 423 may include the same material as the insulating layer 418.

In some examples, the material of the first conductive layer 421 includes titanium nitride, the materials of the sub isolation structure 423 and the insulating layer 418 both include silicon nitride, and the material of the dielectric layer 422 includes silicon oxide.

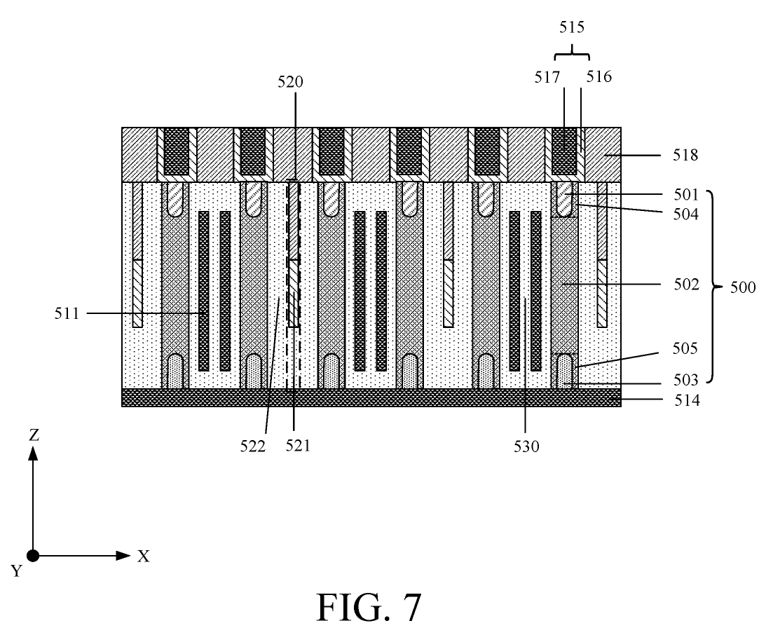

In some examples, FIG. 7 is a structural diagram of a semiconductor device provided by the present disclosure. Referring to FIG. 7, the semiconductor device includes a semiconductor body 500, a word line structure 511, an insulation layer 518, a connection structure 515 (including a second conductive layer 516 and a conductive structure 517), a bit line structure 514, a first isolation structure 520 (including a first conductive layer 521), a dielectric layer 522, and a second isolation structure 530. The semiconductor body 500 includes a first portion 501, a second portion 502, and a third portion 503 arranged along a third direction. A material of the first portion 501, a material of the second portion 502, and a material of the third portion 503 all include a metal semiconductor oxide, and both the chemical composition of the material of the first portion 501 and the chemical composition of the material of the third portion 503 are different from that of the material of the second portion 502.

Here, the semiconductor body 500 further includes a fourth portion 504 and a fifth portion 505, which are located on two opposite sides of the second portion 502 along the third direction, respectively. The fourth portion 504 surrounds the first portion 501 and is connected to the connection structure 515. The fifth portion 505 surrounds the third portion 503 and is connected to the bit line structure 514.

In some examples, both the fourth portion 504 and the fifth portion 505 are connected to the second portion 502, and both the chemical composition of the material of the fourth portion 504 and the chemical composition of the material of the fifth portion 505 are the same as the chemical composition of the material of the second portion 502.

In some examples, the second portion 502 is located in the third direction between two sides of the word line structure 511 that are opposite in the third direction.

In an example of the present disclosure, there may be a larger contact area between the first portion 501 and the fourth portion 504 and between the third portion 503 and the fifth portion 505, so that the contact resistance between different metal semiconductor oxides in the semiconductor body 500 may be further reduced on the basis of shortening the channel extension region to reduce the resistance of the semiconductor body 500, thereby further increasing the on-state current of the transistor including the semiconductor body 500.

It should be noted that the above examples mainly describe the differences between the structure of the semiconductor device shown in FIG. 6 and the structure of the semiconductor device shown in FIG. 3, as well as the differences between the structure of the semiconductor device shown in FIG. 7 and the structure of the semiconductor device shown in FIG. 3. The material composition of the semiconductor body and the connection modes of other structures may refer to the description of the semiconductor device shown in FIG. 3 in the previous examples, and will not be repeated here.

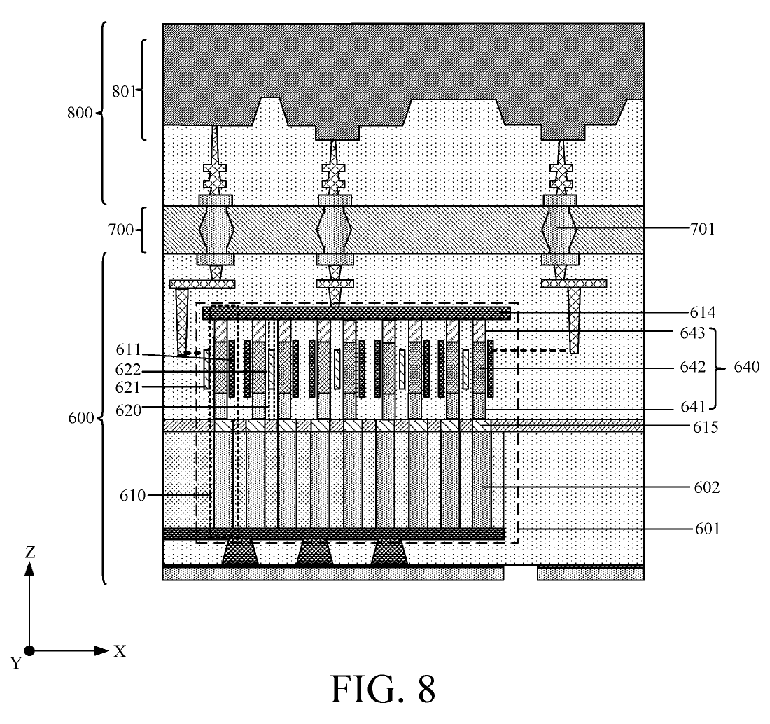

In some examples, FIG. 8 is a structural diagram of a memory device including a semiconductor device provided by an example of the present disclosure. The semiconductor device includes a memory array 601 and a peripheral circuit 801 coupled to the memory array 601. The memory array 601 includes a plurality of semiconductor bodies 640, and a plurality of capacitor structures 602 arranged in an array along the first and second directions. The plurality of capacitor structures 602 and the plurality of semiconductor bodies 640 are stacked along a third direction, and one capacitor structure 602 is coupled to a first portion 641 of one semiconductor body 640.

In some examples, the structures of the semiconductor body 640, the word line structure 611, the bit line structure 614, the connection structure 615, and the first conductive layer 621 in the memory array 601 may refer to the descriptions of FIGS. 3, 5, 6, or 7 in the above examples.

In some examples, the capacitor structure 602 may be coupled to the semiconductor body 640 through the connection structure 615. It should be noted that the structure of capacitor structure 602 is not limited in the present disclosure.

In some examples, referring to FIGS. 8 and 2, the peripheral circuit 801 may include a sense amplifier circuit 1221, a row decoder 1222, a column decoder 1223, an input/output buffer 1224, and other circuits. The memory array 601 may be coupled to the peripheral circuit 801 through a word line structure 611 and a bit line structure 614. The peripheral circuit 801 may be configured to perform read operation, erase operation, write operation, refresh operation, etc. on the memory cells 610 in the memory array 601. Here, a memory cell 610 include a semiconductor body 640 and a capacitor structure 602.

In an example of the present disclosure, the semiconductor body includes a first portion, a second portion, and a third portion arranged along a third direction. A material of the first portion, a material of the second portion, and a material of the third portion all include a metal semiconductor oxide, and both the chemical composition of the material of the first portion and the chemical composition of the material of the third portion are different from that of the material of the second portion. In an example, the material of the first portion and the material of the third portion may have a higher electron mobility, so that the resistance of the semiconductor body, the contact resistance between the semiconductor body and the connection structure, and the contact resistance between the semiconductor body and the bit line structure are all lower. In addition, the material of the second portion may have higher ionization energy and stability, enabling the transistor including the semiconductor body to have both a higher on-state current and a lower off-state current.

In an example of the present disclosure, the transistor including the semiconductor body has a higher on-state current, and when it is necessary to perform read and write operations on the memory cell, the speed of charging and discharging the capacitor structure may be faster, thereby improving the read and write speed of the semiconductor device. The transistor including the semiconductor body has a lower off-state current, which may reduce the leakage current of the transistor. When the memory cell has been written with data, the charge in the capacitor structure may be held for a longer time, thereby improving the data retention capability of the semiconductor device.

Based on similar concepts to the aforementioned semiconductor devices, the present disclosure further provides a memory device. Referring to FIG. 8, the memory device includes a memory array 601 and a peripheral circuit 801 coupled to the memory array 601. The memory array 601 includes a plurality of memory cells 610 arranged in an array along a first direction and a second direction. The memory cell 610 includes a semiconductor body 640 and a capacitor structure 602 stacked along a third direction. The first direction intersects the second direction, and both of them are perpendicular to the third direction. The semiconductor body 640 includes at least a first portion 641, a second portion 642, and a third portion 643 arranged along the third direction. The second portion 642 is located between the first portion 641 and the third portion 643 in the third direction. The first portion 641 is coupled to the capacitor structure 602. A material of the first portion 641, a material of the second portion 642, and a material of the third portion 643 all include a metal semiconductor oxide, and the chemical composition of the material of the first portion 641 and the chemical composition of the material of the third portion 643 is different from that of the material of the second portion 642.

In some examples, the elemental composition of the material of the first portion 641 is different from that of the material of the second portion 642, or the elemental composition of the material of the first portion 641 is the same as that of the material of the second portion 642 and the elemental ratio of the material of the first portion 641 is different from that of the material of the second portion 642. And the elemental composition of the material of the third portion 643 is different from that of the material of the second portion 642, or the elemental composition of the material of the third portion 643 is the same as that of the material of the second portion 642 and the elemental ratio of the material of the third portion 643 is different from that of the material of the second portion 642.

In some examples, the material of the semiconductor body 640 includes at least one of indium element, gallium element, or zinc element.

In some examples, both the materials of the first portion 641 and the third portion 643 include at least one of indium zinc oxide, indium tin oxide, or indium tin zinc oxide.

In some examples, the material of the second portion 642 includes at least one of aluminum element or gallium element.

In some examples, the material of the second portion 642 includes at least one of indium gallium zinc oxide, indium aluminum zinc oxide, or indium aluminum gallium zinc oxide.

In some examples, the material of the first portion 641, the material of the second portion 642, and the material of the third portion 643 all include indium element, and both the ratio of indium element in the material of the first portion 641 and the ratio of indium element in the material of the third portion 643 are higher than that of indium element in the material of the second portion 642.

In some examples, the memory device further comprises: a plurality of word line structures 611 extending along the second direction and arranged along the first direction, wherein one of the word line structures 611 is located in the first direction on at least one side of a plurality of semiconductor bodies 640 arranged along the second direction.

In some examples, the second portion 642 is located in the third direction between two sides of the word line structure 611 that are opposite in the third direction.

In some examples, the ratio of the size of the second portion 642 in the third direction to the size of the semiconductor body 640 in the third direction ranges from 55% to 80%.

In some examples, the memory device further comprises: connection structures 615 located on one of two opposite sides of the semiconductor body 640 along the third direction, wherein one of two opposite ends of one of the connection structures 615 in the third direction is connected to a first portion 641 of one semiconductor body 640, and the other end of two opposite ends of the one of the connection structures 615 in the third direction is connected to the capacitor structure 602; bit line structures 614 located on the other side of two opposite sides of the semiconductor body 640 along the third direction, wherein one of the bit line structures 614 is connected to third portions 643 of a plurality of semiconductor bodies 640 arranged along the first direction.

In some examples, referring to FIGS. 7 and 8, the semiconductor body 640 may have a structure similar to that of the semiconductor body 500, and further includes a fourth portion and a fifth portion, which are located on two opposite sides of the second portion 642 along the third direction, respectively. The fourth portion surrounds the first portion 641 and is connected to the connection structure 615. The fifth portion surrounds the third portion 643 and is connected to the bit line structure 614.

In some examples, both the fourth portion and the fifth portion are connected to the second portion 642, and both the chemical composition of the material of the fourth portion and the chemical composition of the material of the fifth portion are the same as that of the material of the second portion 642.

In some examples, the memory device further comprises: a first isolation structure 620 located on one of two opposite sides of the semiconductor body 640 along the first direction, wherein the first isolation structure 620 includes a first conductive layer 621 extending along the second direction; and a dielectric layer 622 located between the first conductive layer 621 and the semiconductor body 640 in the first direction.

In some examples, the first conductive layer 621 is located in the third direction between two sides of the second portion 642 that are opposite in the third direction.

In some examples, referring to FIG. 8, the memory device includes: a first semiconductor structure 600 and a second semiconductor structure 800 stacked along a third direction; and a bonding layer 700 located between the first semiconductor structure 600 and the second semiconductor structure 800. The memory array 601 is located in the first semiconductor structure 600. The peripheral circuit 801 is located in the second semiconductor structure 800. The memory array 601 and the peripheral circuit 801 are coupled through the bonding structure 701 in the bonding layer 700.

In some examples, the bonding layer 700 may include a hybrid bonding layer, and the bonding structure 701 may include a copper-copper bonding structure. The word line structure 611, the bit line structure 614, and the first conductive layer 621 in the memory array 601 may be coupled to the bonding structure 701 in the bonding layer 700 through conductive interconnect structures, and coupled to CMOS device in the peripheral circuit 801 through the conductive interconnect structures in the second semiconductor structure 800, thereby coupling the memory array 601 to the peripheral circuit 801.

In the memory device provided in the present disclosure, the semiconductor body includes a first portion, a second portion, and a third portion arranged along a third direction. A material of the first portion, a material of the second portion, and a material of the third portion all include a metal semiconductor oxide, and both the chemical composition of the material of the first portion and the chemical composition of the material of the third portion are different from that of the material of the second portion. In an example, the material of the first portion and the material of the third portion may have a higher electron mobility, so that the resistance of the semiconductor body, the contact resistance between the semiconductor body and the connection structure, and the contact resistance between the semiconductor body and the bit line structure are all lower. In addition, the material of the second portion may have higher ionization energy and stability, enabling the transistor including the semiconductor body to have both a higher on-state current and a lower off-state current.

In the memory device provided in the present disclosure, the transistor including the semiconductor body has a higher on-state current, and thus may have strong driving capability. As a result, when it is necessary to perform read and write operations on the memory cell, the charging and discharging speed of the capacitor structure may be faster, thereby improving the read and write speed of the memory device. The transistor including the semiconductor body has a lower off-state current, so that the leakage current of the transistor may be reduced. As a result, when the memory cell has been written with data, the charge in the capacitor structure may be held for a longer time, thereby improving the data retention capability of the memory device.

The present disclosure further provides a memory system. The memory system may comprises: at least one semiconductor device comprising a plurality of semiconductor bodies arranged in an array along first and second directions, wherein the semiconductor body comprises at least a first portion, a second portion, and a third portion arranged along a third direction, the first direction intersects the second direction, and both of them are perpendicular to the third direction, the second portion is located between the first portion and the third portion in the third direction, a material of the first portion, a material of the second portion, and a material of the third portion all include a metal semiconductor oxide, and the chemical composition of the material of the first portion and the chemical composition of the material of the third portion is different from that of the material of the second portion; and a controller coupled to the at least one semiconductor device and configured to control the semiconductor device.

Here, the semiconductor device may be a semiconductor device including a semiconductor body provided in any of the above examples. Therefore, the effects that may be achieved by the semiconductor devices in the above examples may be achieved by the memory system, and the functions of the memory system may refer to the descriptions of FIGS. 1 and 2 in the above examples. The semiconductor device may be the memory device 120 or a part of the memory device 120 in the memory system 10, and the controller may be the controller 110 in the memory system 10, which will not be repeated here.

Based on similar concepts to the aforementioned semiconductor devices, the present disclosure further provides a forming method of a semiconductor device, comprising: forming a plurality of semiconductor bodies arranged in an array along a first direction and a second direction, wherein the semiconductor body comprises at least a first portion, a second portion, and a third portion arranged along a third direction, the first direction intersects the second direction, and both of them are perpendicular to the third direction, the second portion is located between the first portion and the third portion in the third direction, a material of the first portion, a material of the second portion, and a material of the third portion all include a metal semiconductor oxide, and both the chemical composition of the material of the first portion and the chemical composition of the material of the third portion are different from that of the material of the second portion.

Here, the plurality of semiconductor bodies formed by the forming method of the semiconductor device provided by an example of the present disclosure may be the semiconductor bodies in any of the above examples, which include a first portion, a second portion, and a third portion arranged along a third direction.

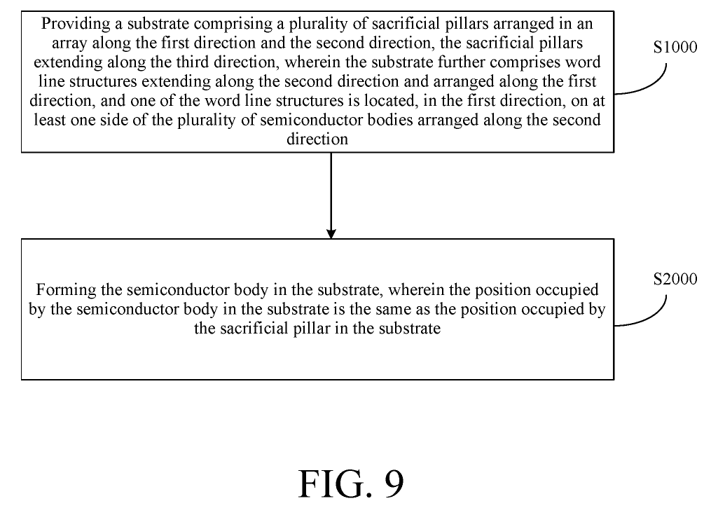

In some examples, FIG. 9 is a schematic flowchart of a forming method of a semiconductor device provided by an example of the present disclosure, which includes the following operations:

Operation S1000: providing a substrate comprising a plurality of sacrificial pillars arranged in an array along the first direction and the second direction, the sacrificial pillars extending along the third direction, wherein the substrate further comprises word line structures extending along the second direction and arranged along the first direction, and one of the word line structures is located in the first direction on at least one side of the plurality of semiconductor bodies arranged along the second direction; and

Operation S2000: forming the semiconductor body in the substrate, wherein the position occupied by the semiconductor body in the substrate is the same as the position occupied by the sacrificial pillar in the substrate.

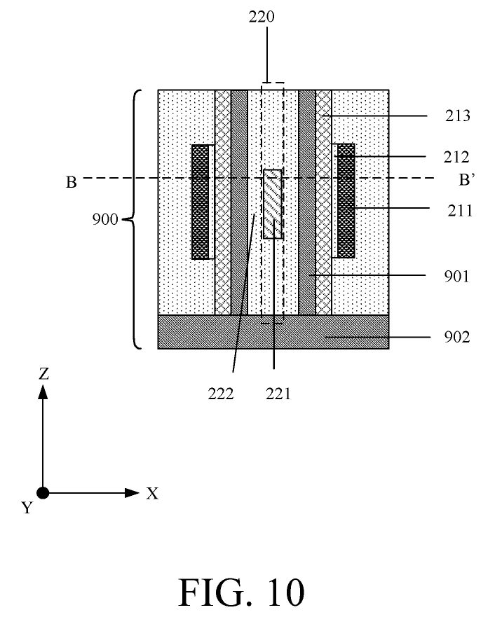

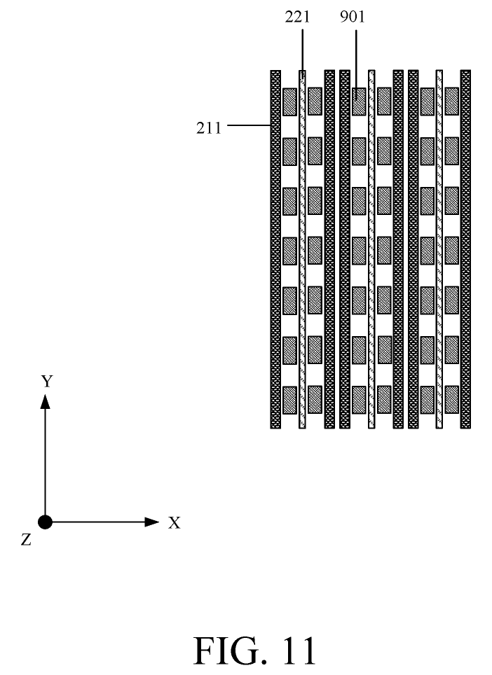

In some examples, referring to FIGS. 10 and 11, wherein FIG. 11 is a cross-sectional view taken along the BB' line of FIG. 10, performing operation S1000 may include: providing a substrate 900 including a plurality of sacrificial pillars 901 arranged in an array along a first direction and a second direction, the sacrificial pillars 901 extending in a third direction, wherein the substrate 900 also includes word line structures 211 extending along the second direction and arranged along the first direction, and one of the word line structures 211 is located in the first direction on at least one side of the plurality of sacrificial pillars 901 arranged along the second direction.

In some examples, performing operation S2000 may include forming the semiconductor body 200 in the substrate 900, wherein the position occupied by the semiconductor body 200 in the substrate 900 is the same as the position occupied by the sacrificial pillar 901 in the substrate 900. Next, the forming method of the semiconductor device provided in the present disclosure will be described by an example of forming two adjacent semiconductor bodies 200 in the first direction in the substrate 900.

In some examples, referring to FIG. 10, the substrate 900 also includes a semiconductor layer 902, and the material of the sacrificial pillar 901 may be the same as that of the semiconductor layer 902. For example, both the sacrificial pillar 901 and the semiconductor layer 902 may include single crystal silicon.

In some examples, referring to FIGS. 10 and 11, the substrate 900 further includes a first isolation structure 220 and a dielectric layer 222. The first isolation structure 220 is located on one of two opposite sides of the sacrificial pillar 901 along the first direction, and includes a first conductive layer 221 extending along the second direction. The dielectric layer 222 is located between the first conductive layer 221 and the sacrificial pillar 901 in the first direction.

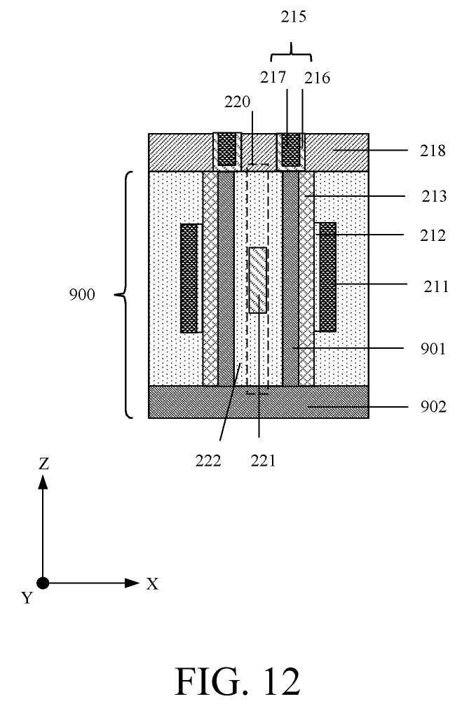

In some examples, referring to FIGS. 10 and 12, the forming method of a semiconductor device further includes: forming an insulating layer 218 on one of two opposite sides of the substrate 900 in the third direction, and forming a plurality of connection structures 215 that penetrate through the insulating layer 218 along the third direction.

In some examples, the process of forming the connection structure 215 may include: forming an insulating layer 218 on the substrate 900 through a deposition process; etching the insulating layer 218 to form a plurality of openings exposing the sacrificial pillars 901 in the insulating layer 218; forming a second conductive layer 216 that covers the sidewalls and bottom of the opening, and forming a conductive structure 217 in the remaining space of the openings, wherein the conductive structure 217 and the second conductive layer 216 together constitute the connection structure 215.

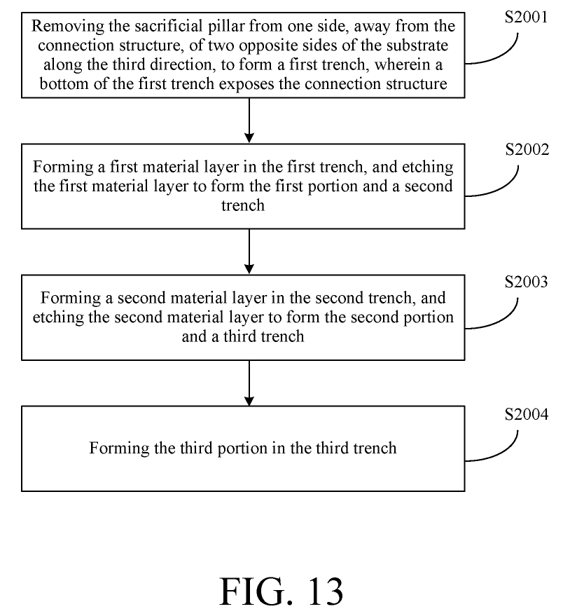

In some examples, FIG. 13 is a schematic flow chart I of forming a semiconductor body in a substrate provided by an example of the present disclosure. Referring to FIG. 13, the process of performing operation S2000 may include:

Operation S2001: removing the sacrificial pillar from one side, away from the connection structure, of two opposite sides of the substrate along the third direction, to form a first trench, wherein a bottom of the first trench exposes the connection structure;

Operation S2002: forming a first material layer in the first trench, and etching the first material layer to form the first portion and a second trench;

Operation S2003: forming a second material layer in the second trench, and etching the second material layer to form the second portion and a third trench; and

Operation S2004: forming the third portion in the third trench.

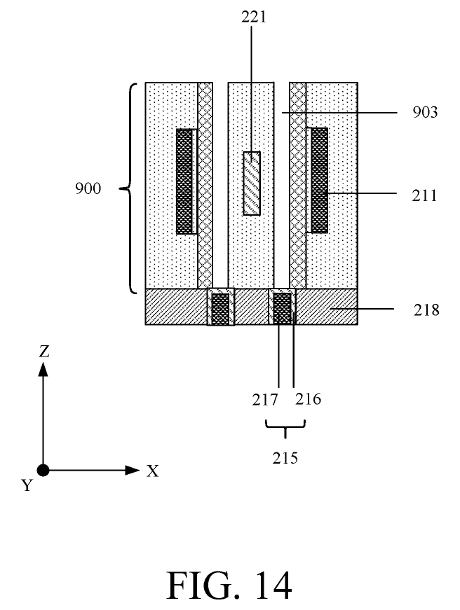

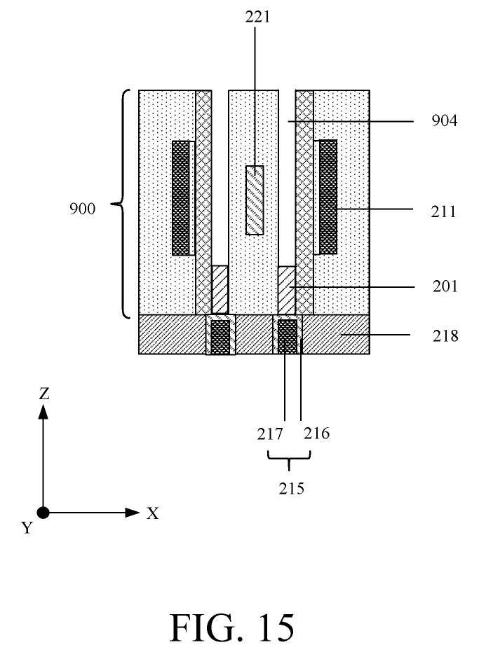

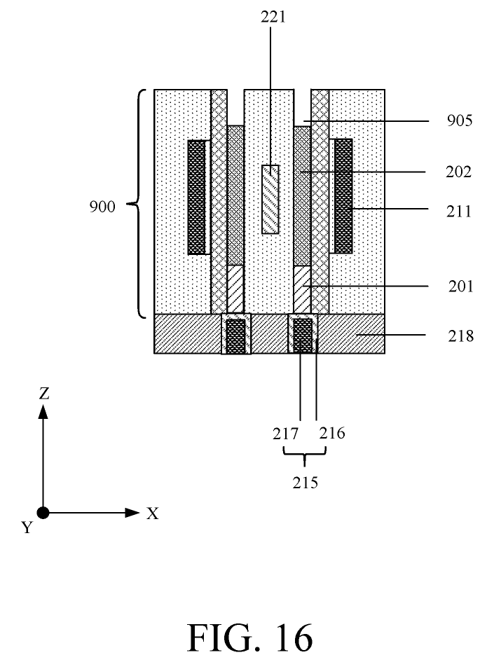

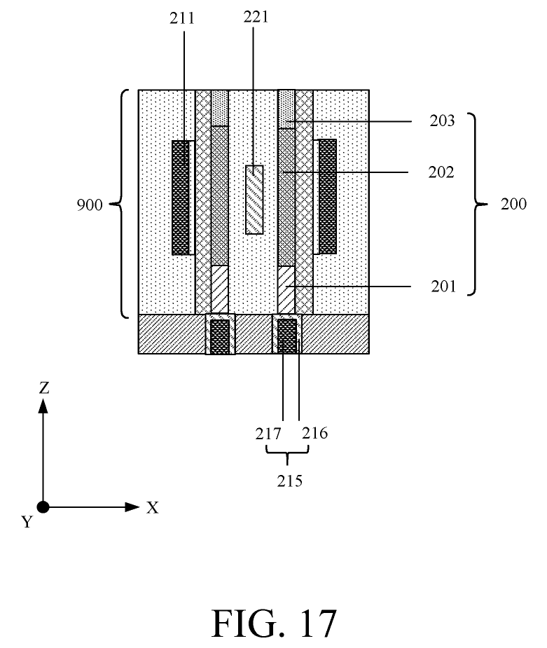

In some examples, referring to FIGS. 12 and 14, the process of performing operation S2001 may include: removing the sacrificial pillar 901 and the semiconductor layer 902 from one side, away from the connection structure 215, of two opposite sides of the substrate 900 along the third direction, to form a first trench 903. The bottom of the first trench 903 exposes the connection structure 215. Referring to FIGS. 14 and 15, the process of performing operation S2002 may include: forming a first material layer in the first trench 903, and etching the first material layer to form the first portion 201 and a second trench 904. Referring to FIGS. 15 and 16, the process of performing operation S2003 may include: forming a second material layer in the second trench 904, and etching the second material layer to form the second portion 202 and a third trench 905. Referring to FIGS. 16 and 17, the process of performing operation S2004 may include: forming a third portion 203 in the third trench 905, wherein the first portion 201, the second portion 202, and the third portion 203 constitute the semiconductor body 200.

In some examples, the first material layer, the second material layer, and the third material layer may be formed by a deposition process, and the first material layer, the second material layer, and the third material layer may be etched by a wet etching process to form the first portion 201, the second portion 202, and the third portion 203. Here, the first material layer, the second material layer, and the third material layer all include a metal semiconductor oxide, and both the chemical composition of the first material layer and the chemical composition of the third material layer are different from the chemical composition of the second material layer.

In some examples, referring to FIG. 15, when etching the first material layer to form the first portion 201, the top surface of the first portion 201 may be made lower than the bottom surface of the word line structure 211; and referring to FIG. 16, when etching the second material layer to form the second portion 202, the top surface of the second portion 202 may be made higher than the top surface of the word line structure 211. In other examples, when etching the first material layer to form the first portion 201, the top surface of the first portion 201 may be made higher than the bottom surface of the word line structure 211, and when etching the second material layer to form the second portion 202, the top surface of the second portion 202 may be made lower than the top surface of the word line structure 211.

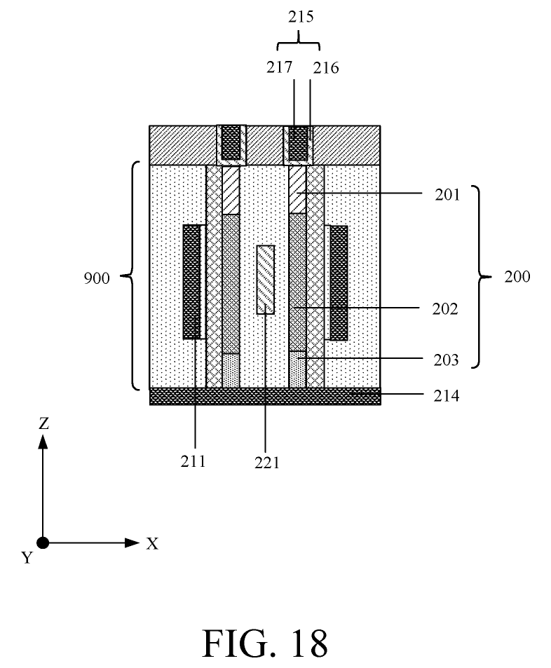

In some examples, referring to FIGS. 17 and 18, the forming method of a semiconductor device further includes: forming bit line structures 214 on one side, away from the connection structure 215, of two opposite sides of the semiconductor body 200 along the third direction. One of the bit line structures 214 is connected to third portions 203 of a plurality of semiconductor bodies 200 arranged along the first direction.

In some examples, the structure of the semiconductor device formed by the forming method of the semiconductor device shown in FIGS. 9 and 13 may be as shown in FIG. 3.

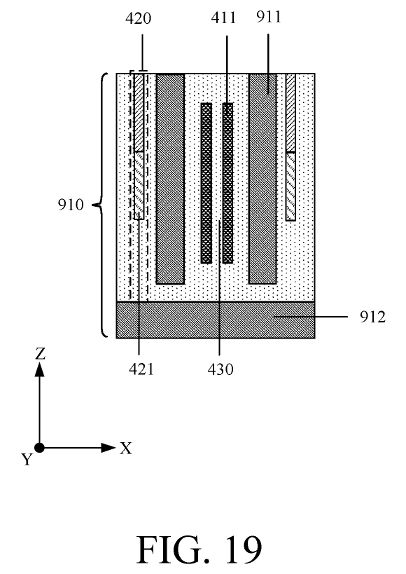

In some examples, referring to FIG. 19, performing operation S1000 may include: providing a substrate 910 including a plurality of sacrificial pillars 911 arranged in an array along the first and second directions, the sacrificial pillars 911 extending in the third direction, wherein the substrate 910 also includes word line structures 411 extending along the second direction and arranged along the first direction, and one of the word line structures 411 is located in the first direction on at least one side of the plurality of sacrificial pillars 911 arranged along the second direction.

In some examples, referring to FIG. 19, the substrate 910 also includes a semiconductor layer 912, and the material of the sacrificial pillar 911 may be the same as that of the semiconductor layer 912. For example, both the sacrificial pillar 911 and the semiconductor layer 912 may include single crystal silicon. Here, the sacrificial pillar 911 may not be connected to the semiconductor layer 912.

In some examples, referring to FIG. 19, the substrate 910 further includes a first isolation structure 420, wherein the first isolation structure 420 is located on one of two opposite sides of the sacrificial pillar 911 along the first direction, and includes a first conductive layer 421 extending along the second direction.

In some examples, referring to FIG. 19, the substrate 910 further includes a second isolation structure 430 located between two adjacent word line structures 411 in the first direction, and the two adjacent word line structures 411 in the first direction are symmetrically distributed on both sides of the second isolation structure 430 along the first direction.

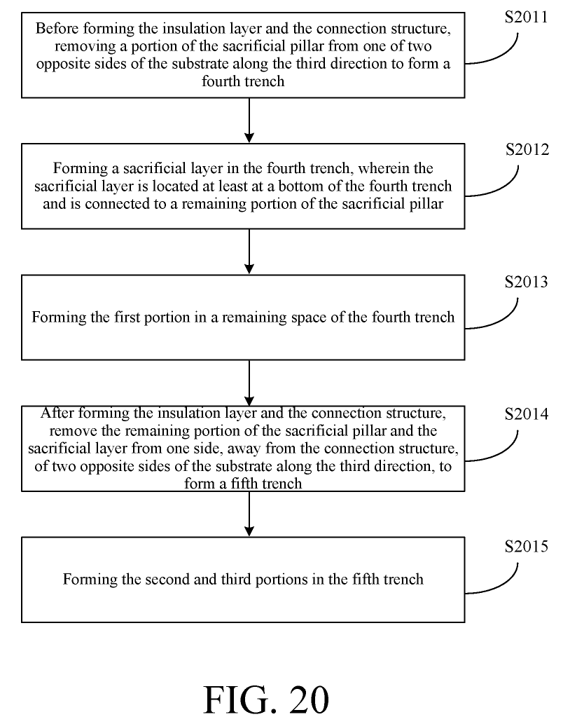

In some examples, FIG. 20 is a schematic flow chart II of forming a semiconductor body in a substrate provided by an example of the present disclosure. Referring to FIG. 20, the process of performing operation S2000 may include:

Operation S2011: before forming the insulation layer and the connection structure, removing a portion of the sacrificial pillar from one of two opposite sides of the substrate along the third direction to form a fourth trench;

Operation S2012: forming a sacrificial layer in the fourth trench, wherein the sacrificial layer is located at least at a bottom of the fourth trench and is connected to a remaining portion of the sacrificial pillar;

Operation S2013: forming the first portion in a remaining space of the fourth trench;

Operation S2014: after forming the insulation layer and the connection structure, removing the remaining portion of the sacrificial pillar and the sacrificial layer from one side, away from the connection structure, of two opposite sides of the substrate along the third direction, to form a fifth trench; and

Operation S2015: forming the second and third portions in the fifth trench.

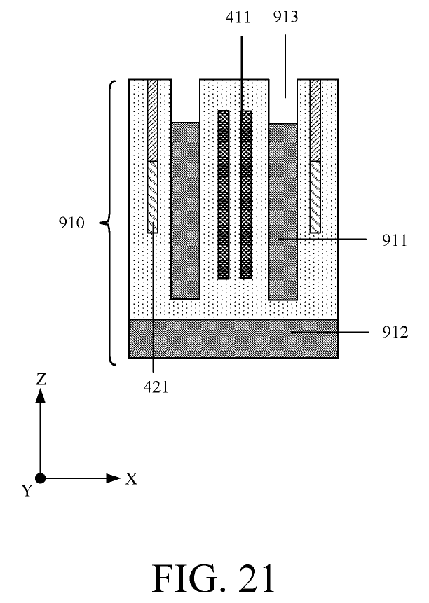

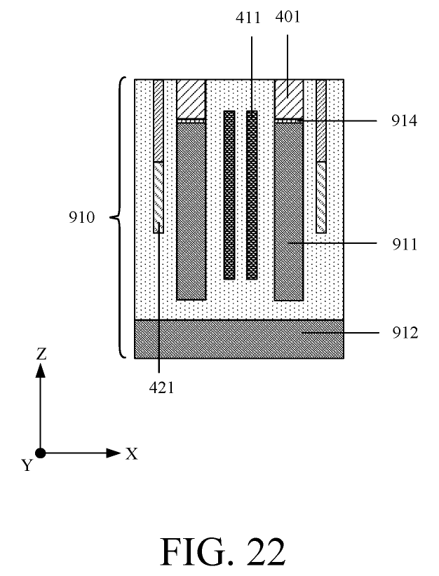

In some examples, referring to FIGS. 19 and 21, the process of performing operation S2011 may include: removing a portion of the sacrificial pillar 911 from one of two opposite sides of the substrate 910 along the third direction to form a fourth trench 913. Referring to FIGS. 21 and 22, the process of performing operations S2012 and S2013 may include: forming a sacrificial layer 914 in the fourth trench 913, wherein the sacrificial layer 914 is located at the bottom of the fourth trench 913 and is connected to the remaining portion of the sacrificial pillar 911; and forming the first portion 401 in the remaining space of the fourth trench 913.

In some examples, the material of the sacrificial layer 914 may include a metal oxide, such as tungsten oxide, aluminum oxide, etc.

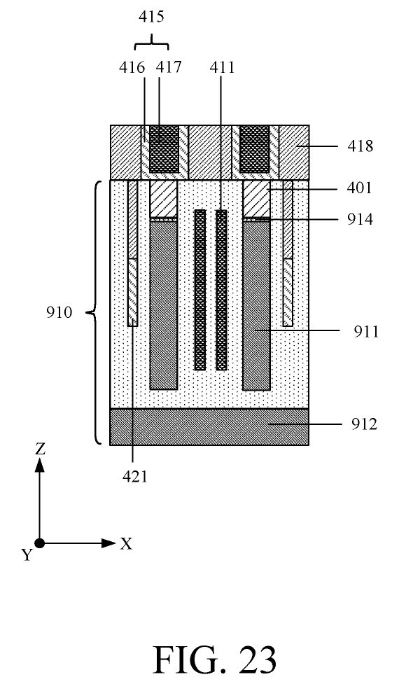

In some examples, referring to FIGS. 22 and 23, the forming method of a semiconductor device further includes: forming an insulating layer 418 on one of two opposite sides of the substrate 910 along the third direction, and forming a plurality of connection structures 415 that penetrate through the insulating layer 418 along the third direction.

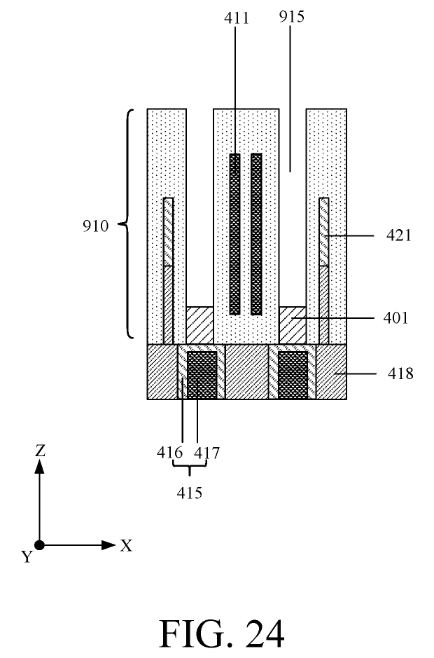

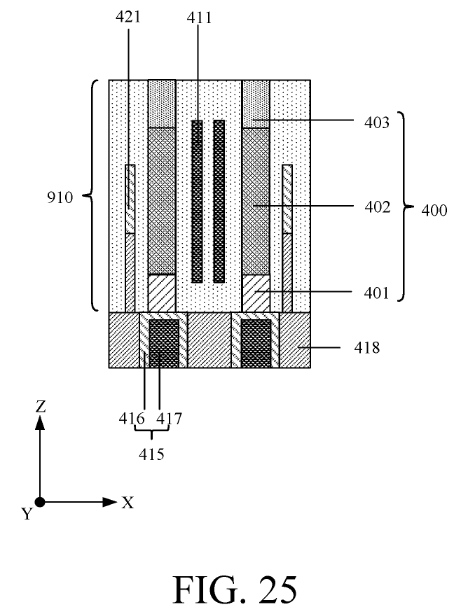

In some examples, referring to FIGS. 23 and 24, the process of performing operation S2014 may include: after forming the insulation layer 418 and the connection structure 415, removing the remaining portion of the sacrificial pillar 911 and the sacrificial layer 914 from one side, away from the connection structure 415, of two opposite sides of the substrate 910 along the third direction, to form a fifth trench 915. Referring to FIGS. 24 and 25, the process of performing operation S2015 may include forming the second portion 402 and the third portion 403 in the fifth trench 915. The first portion 401, the second portion 402, and the third portion 403 constitute the semiconductor body 400.

In some examples, the remaining portion of the sacrificial pillar 911 and the sacrificial layer 914 may be removed through a wet etching process, and since the material of the sacrificial pillar 911 is different from that of the sacrificial layer 914, the sacrificial layer 914 may serve as an etching stop layer when removing the remaining portion of the sacrificial pillar 911 through the wet etching process, and then, the sacrificial layer 914 may be removed through another etchant to expose the first portion 401.

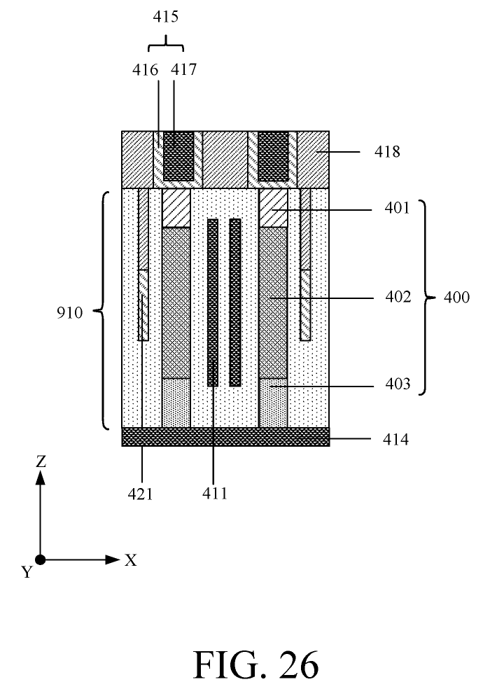

In some examples, referring to FIGS. 25 and 26, the forming method of a semiconductor device further includes: forming bit line structures 414 on one side, away from the connection structure 415, of two opposite sides of the semiconductor body 400 along the third direction, wherein one of the bit line structures 414 is connected to the third portions 403 of a plurality of semiconductor bodies 400 arranged along the first direction.

In some examples, the structure of the semiconductor device formed by the forming method of the semiconductor device shown in FIGS. 9 and 20 may be as shown in FIG. 6.

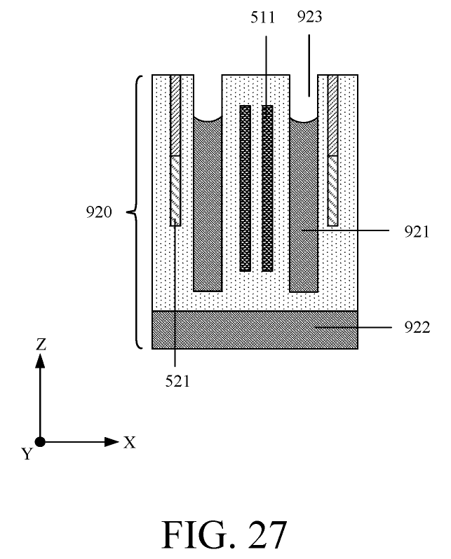

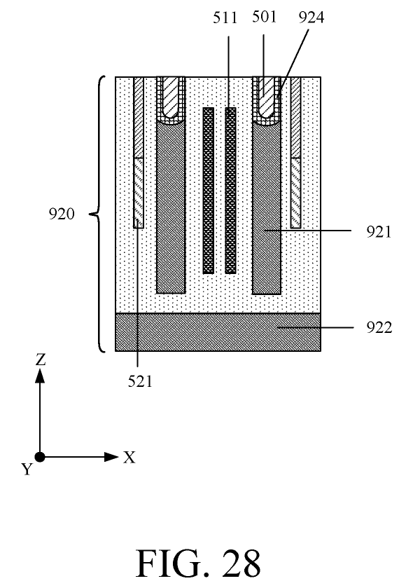

In other examples, referring to FIG. 27, a substrate 920 is provided, which includes a sacrificial pillar 921, a semiconductor layer 922, a first conductive layer 521, and a word line structure 511. The process of performing operation S2011 may include: removing a portion of the sacrificial pillar 921 from one of two opposite sides of the substrate 920 along the third direction to form a fourth trench 923. Referring to FIGS. 27 and 28, the process of performing operations S2012 and S2013 may include: forming a sacrificial layer 924 in the fourth trench 923, wherein the sacrificial layer 924 is located at the bottom and sidewalls of the fourth trench 923, and is connected to the remaining portion of the sacrificial pillar 921; and forming the first portion 501 in the remaining space of the fourth trench 923.

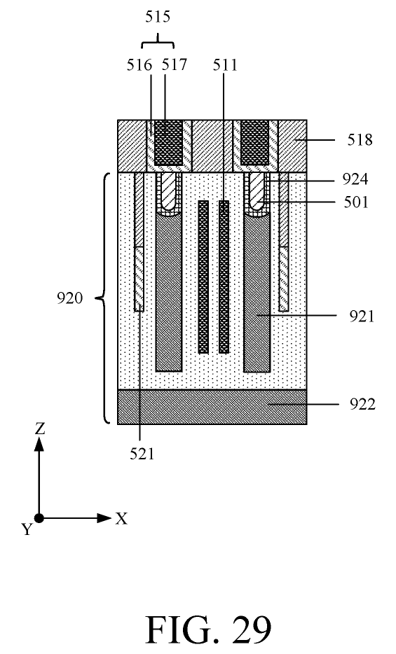

In some examples, referring to FIGS. 28 and 29, the forming method of a semiconductor device further includes: forming an insulating layer 518 on one of two opposite sides of the substrate 920 along the third direction, and forming a plurality of connection structures 515 that penetrate through the insulating layer 518 along the third direction. The connection structure 515 include a second conductive layer 516 and a conductive structure 517.

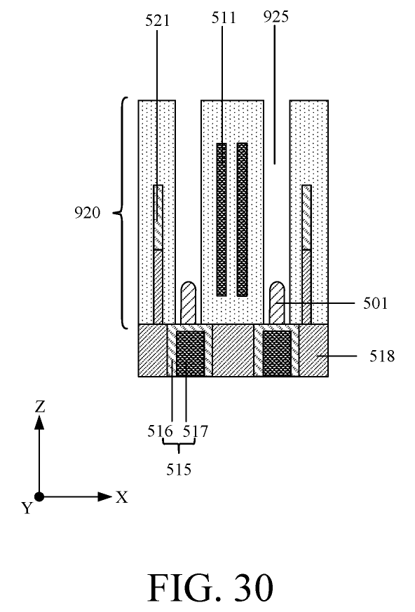

In some examples, referring to FIGS. 29 and 30, the process of performing operation S2015 may include: after forming the insulation layer 518 and the connection structure 515, removing the remaining portion of the sacrificial pillar 921 and the sacrificial layer 924 from one side, away from the connection structure 515, of two opposite sides of the substrate 920 along the third direction, to form a fifth trench 925.

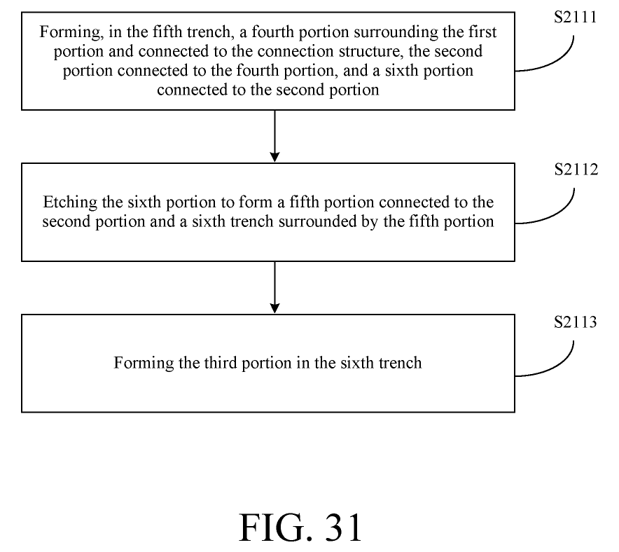

In some examples, FIG. 31 is a schematic flow chart of forming a second portion and a third portion in a fifth trench provided by an example of the present disclosure. Referring to FIG. 31, the process of performing operation S2016 may include:

Operation S2111: forming, in the fifth trench, a fourth portion surrounding the first portion and connected to the connection structure, the second portion connected to the fourth portion, and a sixth portion connected to the second portion;

Operation S2112: etching the sixth portion to form a fifth portion connected to the second portion and a sixth trench surrounded by the fifth portion; and

Operation S2113: forming the third portion in the sixth trench.

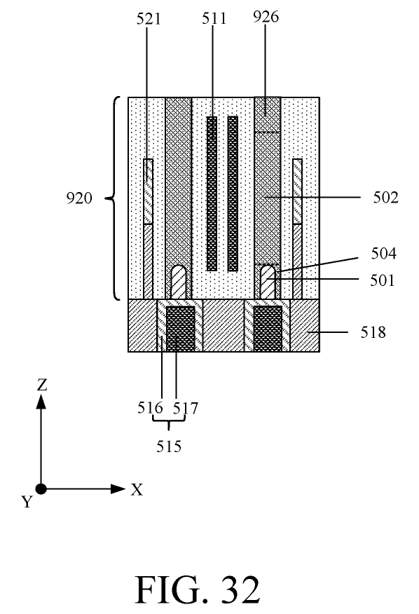

In some examples, referring to FIGS. 30 and 32, the process of performing operation S2111 may include: forming, in the fifth trench 925, a fourth portion 504 surrounding the first portion 501 and connected to the connection structure 515, the second portion 502 connected to the fourth portion 504, and a sixth portion 926 connected to the second portion 502. Here, the fourth portion 504, the second portion 502, and the sixth portion 926 may include the same material. The fourth portion 504 surrounds the first portion 501, and thus there may be a larger contact area between the fourth portion 504 and the first portion 501.

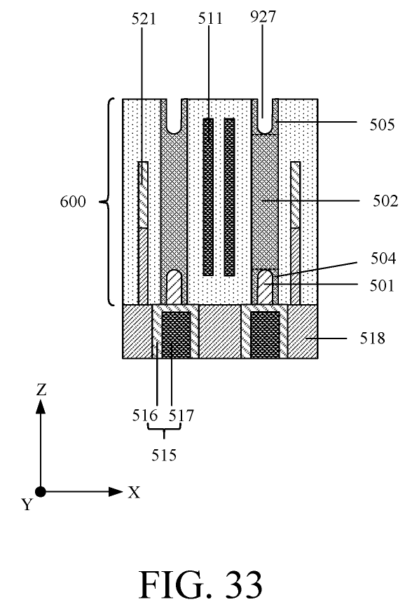

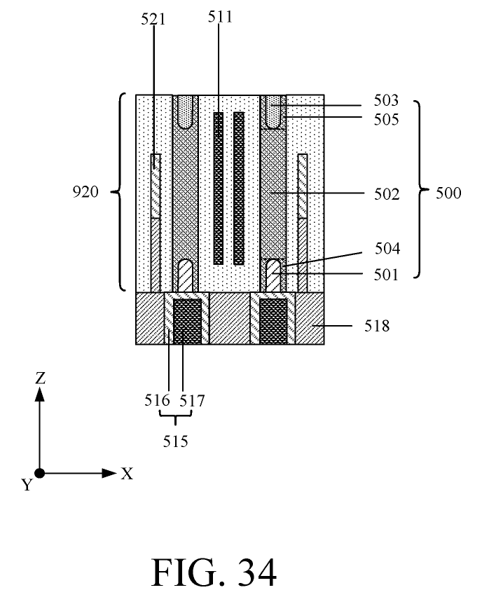

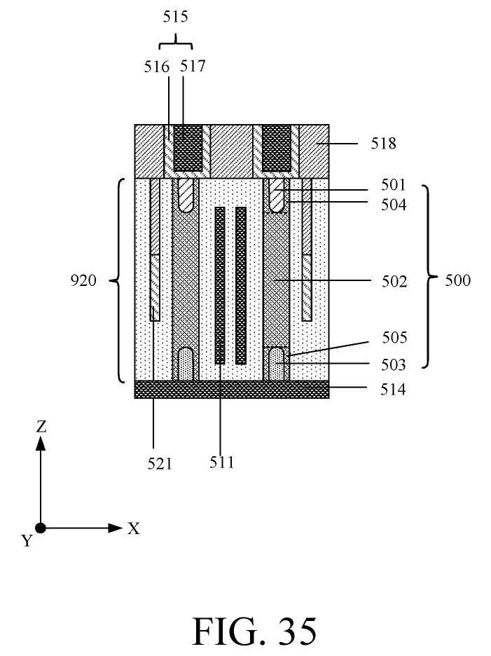

In some examples, referring to FIGS. 32 and 33, the process of performing operation S2112 may include: etching the sixth portion 926 to form a fifth portion 505 connected to the second portion 502 and a sixth trench 927 surrounded by the fifth portion 505; and with reference to FIGS. 33 and 34, forming the third portion 503 in the sixth trench 927. The fifth portion 505 surrounds the third portion 503, and thus there may be a larger contact area between the fifth portion 505 and the third portion 503. The first portion 501, the second portion 502, the third portion 503, the fourth portion 504, and the fifth portion 505 constitute the semiconductor body 500.

In some examples, referring to FIGS. 33 and 34, the forming method of a semiconductor device further includes: forming bit line structures 514 on one side, away from the connection structure 515, of two opposite sides of the semiconductor body 500 along the third direction, wherein one of the bit line structures 514 is connected to the third portions 503 and the fifth portions 505 of a plurality of semiconductor bodies 500 arranged along the first direction.

In some examples, the structure of the semiconductor device formed by the forming method of the semiconductor device shown in FIGS. 9, 20, and 31 is shown in FIG. 7.

In examples of the present disclosure, in the semiconductor device obtained by the forming method of the semiconductor device described above, a semiconductor body includes a first portion, a second portion, and a third portion arranged along a third direction, wherein a material of the first portion, a material of the second portion, and a material of the third portion all include a metal semiconductor oxide, and both the chemical compositions of the material of the first portion and the chemical composition of the material of the third portion are different from the chemical composition of the material of the second portion. In an example, the material of the first portion and the material of the third portion may have a higher electron mobility, so that the resistance of the semiconductor body, the contact resistance between the semiconductor body and the connection structure, and the contact resistance between the semiconductor body and the bit line structure are all lower. In addition, the material of the second portion may have higher ionization energy and stability, so that the transistor including the semiconductor body may have both a higher on-state current and a lower off-state current, thus having stronger driving capability and higher reliability.

The features disclosed in several device examples provided in the present disclosure may be combined arbitrarily without conflict to obtain new device examples.

The methods disclosed in several method examples provided in the present disclosure may be combined arbitrarily without conflict to obtain new method examples.

The above description are only implementations of the present disclosure, but the protection scope of the present disclosure is not limited thereto, and changes or replacements that may be easily conceived by any person skilled in the art within the technical scope of the present disclosure should be covered within the protection scope of the present disclosure.

What is claimed is:

1. A semiconductor device, comprising:
a plurality of semiconductor bodies arranged in an array along a first direction and a second direction,
wherein a semiconductor body of the plurality of semiconductor bodies comprises at least a first portion, a second portion, and a third portion arranged along a third direction, and wherein the first direction intersects the second direction, and both of the first direction and the second direction are perpendicular to the third direction,
wherein the second portion is located between the first portion and the third portion in the third direction, and
wherein a material of the first portion, a material of the second portion, and a material of the third portion all comprise a metal semiconductor oxide, and both a chemical composition of the material of the first portion and a chemical composition of the material of the third portion are different from that of the material of the second portion.

2. The semiconductor device of claim 1, wherein:
an elemental composition of the material of the first portion is different from that of the material of the second portion, or the elemental composition of the material of the first portion is same as that of the material of the second portion and an elemental ratio of the material of the first portion is different from that of the material of the second portion, and
an elemental composition of the material of the third portion is different from that of the material of the second portion, or the elemental composition of the material of the third portion is same as that of the material of the second portion and an elemental ratio of the material of the third portion is different from that of the material of the second portion.

3. The semiconductor device of claim 1, wherein a material of the semiconductor body comprises at least one of indium element, gallium element, or zinc element.

4. The semiconductor device of claim 1, wherein the material of the second portion comprises at least one of aluminum element or gallium element.

5. The semiconductor device of claim 1, wherein the material of the first portion, the material of the second portion, and the material of the third portion all include indium element, and both a ratio of indium element in the material of the first portion and a ratio of indium element in the material of the third portion are higher than a ratio of indium element in the material of the second portion.

6. The semiconductor device of claim 1, further comprising:
a plurality of word line structures that extend along the second direction and are arranged along the first direction,
wherein a word line structure of the plurality of word line structures is located, in the first direction, on at least one side of the plurality of semiconductor bodies arranged along the second direction.

7. The semiconductor device of claim 6, wherein the word line structure is located, in the third direction, between two sides of the second portion that are opposite in the third direction.

8. The semiconductor device of claim 6, further comprising:
connection structures located on one side of two opposite sides of the semiconductor body along the third direction, wherein a connection structure of the connection structures is connected to a first portion of a corresponding one of the plurality of semiconductor bodies; and
bit line structures located on the other side of the two opposite sides of the semiconductor body along the third direction, wherein a bit line structure of the bit line structures is connected to third portions of the plurality of semiconductor bodies arranged along the first direction,
wherein the semiconductor body further comprises a fourth portion and a fifth portion, wherein the fourth portion and the fifth portion are respectively located on two opposite sides of the second portion along the third direction, the fourth portion surrounds the first portion and is connected to the connection structure, and the fifth portion surrounds the third portion and is connected to the bit line structure, and
wherein both the fourth portion and the fifth portion are connected to the second portion, and both a chemical composition of a material of the fourth portion and a chemical composition of a material of the fifth portion are same as that of the material of the second portion.

9. The semiconductor device of claim 8, further comprising:
a first isolation structure located on one of two opposite sides of the semiconductor body along the first direction,
wherein the first isolation structure comprises:
a first conductive layer extending along the second direction; and
a dielectric layer located between the first conductive layer and the
semiconductor body in the first direction.

10. The semiconductor device of claim 1, wherein a ratio of a size of the second portion in the third direction to a size of the semiconductor body in the third direction is in a range from 55% to 80%.

11. The semiconductor device of claim 1, comprising a memory array and a peripheral circuit coupled to the memory array,
wherein the memory array comprises the plurality of semiconductor bodies and a plurality of capacitor structures arranged in an array along the first direction and the second direction, the plurality of capacitor structures and the plurality of semiconductor bodies are stacked along the third direction, and a capacitor structure of the plurality of capacitor structures is coupled to a first portion of a corresponding semiconductor body of the plurality of semiconductor bodies.

12. A memory device, comprising:
a memory array; and
a peripheral circuit coupled to the memory array,
wherein the memory array comprises a plurality of memory cells arranged in an array along a first direction and a second direction, wherein a memory cell of the plurality of memory cells comprises a semiconductor body and a capacitor structure stacked along a third direction, and wherein the first direction intersects the second direction, and both of the first direction and the second direction are perpendicular to the third direction,
wherein the semiconductor body comprises at least a first portion, a second portion, and a third portion arranged along the third direction, and wherein the second portion is located between the first portion and the third portion in the third direction, and the first portion is coupled to the capacitor structure, and
wherein a material of the first portion, a material of the second portion, and a material of the third portion all include a metal semiconductor oxide, and both a chemical composition of the material of the first portion and a chemical composition of the material of the third portion are different from that of the material of the second portion.

13. The memory device of claim 12, wherein an elemental composition of the material of the first portion is different from that of the material of the second portion, or the elemental composition of the material of the first portion is same as that of the material of the second portion and an elemental ratio of the material of the first portion is different from that of the material of the second portion, and
wherein an elemental composition of the material of the third portion is different from that of the material of the second portion, or the elemental composition of the material of the third portion is same as that of the material of the second portion and an elemental ratio of the material of the third portion is different from that of the material of the second portion.

14. The memory device of claim 12, wherein a ratio of a size of the second portion in the third direction to a size of the semiconductor body in the third direction ranges from 55% to 80%.

15. The memory device of claim 12, further comprising:
connection structures located on one side of two opposite sides of the semiconductor body along the third direction, wherein one end of two opposite ends of a connection structure of the connection structures in the third direction is connected to a first portion a corresponding semiconductor body of the plurality of semiconductor bodies, and the other end of the two opposite ends of the connection structure of the connection structures in the third direction is connected to the capacitor structure; and
bit line structures located on the other side of the two opposite sides of the semiconductor body along the third direction, wherein a bit line of the bit line structures is connected to the third portions of the plurality of semiconductor bodies arranged along the first direction,
wherein the semiconductor body further comprises a fourth portion and a fifth portion, wherein the fourth portion and the fifth portion are respectively located on two opposite sides of the second portion along the third direction, the fourth portion surrounds the first portion and is connected to the connection structure, and the fifth portion surrounds the third portion and is connected to the bit line structure, and
wherein both the fourth portion and the fifth portion are connected to the second portion, and both a chemical composition of a material of the fourth portion and a chemical composition of a material of the fifth portion are the same as that of the material of the second portion.

16. A method of forming a semiconductor device, comprising:
forming a plurality of semiconductor bodies arranged in an array along a first direction and a second direction, wherein a semiconductor body of the plurality of semiconductor bodies comprises at least a first portion, a second portion, and a third portion arranged along a third direction, and wherein the first direction intersects the second direction, and both of the first direction and the second direction are perpendicular to the third direction,
wherein the second portion is located between the first portion and the third portion in the third direction, a material of the first portion, a material of the second portion, and a material of the third portion all comprise a metal semiconductor oxide, and both a chemical composition of the material of the first portion and a chemical composition of the material of the third portion are different from that of the material of the second portion.

17. The method of claim 16, further comprising:
providing a substrate comprising a plurality of sacrificial pillars arranged in an array along the first direction and the second direction, a sacrificial pillar of the plurality of sacrificial pillars extending along the third direction, wherein the substrate further comprises word line structures that extend along the second direction and are arranged along the first direction, and a word line structure of the word line structures is located, in the first direction, on at least one side of the plurality of sacrificial pillars arranged along the second direction,
wherein forming the plurality of semiconductor bodies comprises:
forming the semiconductor body in the substrate, wherein a position
occupied by the semiconductor body in the substrate is same as a position occupied by the sacrificial pillar in the substrate.

18. The method of claim 17, further comprising:
forming an insulation layer on a first side of two opposite sides of the substrate along the third direction, and
forming a plurality of connection structures that penetrate through the insulation layer along the third direction,
wherein forming the semiconductor body comprises:
removing the sacrificial pillar from one side, away from the connection
structure, of the two opposite sides of the substrate along the third direction, to form a first trench, wherein a bottom of the first trench exposes the connection structure;
forming a first material layer in the first trench, and etching the first material
layer to form the first portion and a second trench;
forming a second material layer in the second trench, and etching the second
material layer to form the second portion and a third trench; and
forming the third portion in the third trench.

19. The method of claim 18, wherein forming the semiconductor body comprises:
before forming the insulation layer and the connection structure, removing a portion of the sacrificial pillar from the first side of the two opposite sides of the substrate along the third direction to form a fourth trench;
forming a sacrificial layer in the fourth trench, wherein the sacrificial layer is located at least at a bottom of the fourth trench and is connected to a remaining portion of the sacrificial pillar;
forming the first portion in a remaining space of the fourth trench;
after forming the insulation layer and the connection structure, removing the remaining portion of the sacrificial pillar and the sacrificial layer from the one side, away from the connection structure, of the two opposite sides of the substrate along the third direction, to form a fifth trench; and
forming the second portion and the third portion in the fifth trench.

20. The forming method of the semiconductor device of claim 19, wherein the sacrificial layer is located at the bottom and sidewall of the fourth trench, and
wherein forming the second portion and the third portion in the fifth trench comprises:
forming, in the fifth trench, a fourth portion surrounding the first portion and
connected to the connection structure, the second portion connected to the fourth portion, and a sixth portion connected to the second portion;
etching the sixth portion to form a fifth portion connected to the second
portion and a sixth trench surrounded by the fifth portion; and
forming the third portion in the sixth trench.
